(19) United States
(12) Patent Application Publication
(10) Pub. No.: US 2026/0247636 A1
(43) Pub. Date: Aug. 20, 2026

(54) CAPACITIVE ELEMENT AND DISPLAY DEVICE

(71) Applicants: SONY SEMICONDUCTOR SOLUTIONS CORPORATION, KANAGAWA (JP); SONY GROUP CORPORATION, TOKYO (JP)

(72) Inventors: TAKASHI TOYODA, KANAGAWA (JP); HARUKI TSUCHIYA, TOKYO (JP); KEI KIMURA, TOKYO (JP); KAZUKI YOKOYAMA, KANAGAWA (JP)

(21) Appl. No.: 19/162,005

(22) PCT Filed: Feb. 27, 2024
(86) PCT No.: PCT/JP2024/004081

§ 371 Date: Sep. 3, 2025

(30) Foreign Application Priority Data
Mar. 16, 2023 (JP) 2023-042236

(51) Int. Cl. H10D 1/68; H10D 86/40; H10D 86/60; H10W 20/40

(52) U.S. Cl. CPC H10D 1/692; H10D 86/441; H10D 86/481; H10D 86/60; H10W 20/40

(57) ABSTRACT

The present disclosure provides a capacitive element and a display device that can suppress a difference in capacitance. A capacitive element including: a first layer body including a first metal body and a second metal body formed in a first layer; and a second layer body including a third metal body and a fourth metal body formed in a second layer different from the first layer, in which the first to fourth metal bodies are formed in an insulator, the first metal body and the third metal body have the same potential, and the second metal body and the fourth metal body have the same potential.

### TECHNICAL FIELD

The present disclosure relates to a capacitive element and a display device.

### BACKGROUND ART

A display device having an organic light emitting diode (OLED) panel is generally known. In this OLED panel, definition enhancement is promoted, and a pixel (subpix) is also miniaturized. Because this causes a layout in the pixel to have many restrictions, miniaturization of the capacitance in the pixel is also promoted. In order to miniaturize such a capacitance, the capacitance includes a plurality of layers of metal-oxide-metal (MOM) structure in some cases. In the capacitance of the MOM structure, if the capacitance can be secured between upper and lower metals, the capacitance can be efficiently increased even with the layout restrictions.

### CITATION LIST

### Patent Document

Patent Document 1: Japanese Patent Application Laid-Open No. 2010-62489

### SUMMARY OF THE INVENTION

### Problems to be Solved by the Invention

However, there is a possibility that the capacitance varies due to the influence of the film thickness of an interlayer insulating film in the longitudinal direction.

Therefore, the present disclosure provides a capacitive element and a display device that can suppress a difference in capacitance.

### Solutions to Problems

In order to solve the above problems, according to the present disclosure, there is provided a capacitive element including:

a first layer body including a first metal body and a second metal body formed in a first layer; and
a second layer body including a third metal body and a fourth metal body formed in a second layer different from the first layer, in which
the first to fourth metal bodies are formed in an insulator, the first metal body and the third metal body have the same potential, and the second metal body and the fourth metal body have the same potential.

The first metal body and the third metal body may be connected by a first metal via, and the second metal body and the fourth metal body may be connected by a second metal via.

The first metal body and the third metal body may be connected by a plurality of the first metal vias, and the second metal body and the fourth metal body may be connected by a plurality of the second metal vias, and
the plurality of first metal vias and the plurality of the second metal vias may be arranged in a lattice pattern.

Each of the first metal vias and each of the second metal vias adjacent to each other may be arranged at an equal distance from each other.

The first layer and the second layer different from the first layer may include parallel layers,
the first metal body and the third metal body may have the same shapes and the second metal body and the fourth metal body may have the same shapes,
the first metal body and the third metal body may overlap each other in a direction orthogonal to the parallel layers, and
the second metal body and the fourth metal body may overlap each other in a direction orthogonal to the parallel layers.

The first metal body may include a first metal having a rectangular parallelepiped shape and a plurality of second metals each having a rectangular parallelepiped shape orthogonal to the first metal,
the second metal body may include a third metal having a rectangular parallelepiped shape and a plurality of fourth metals each having a rectangular parallelepiped shape orthogonal to the third metal, and
the first metal and the third metal may be arranged to face each other, and the plurality of second metals and the plurality of fourth metals may be arranged to face each other.

The first layer body may further include a fifth metal body, and the second layer may body further include a sixth metal body corresponding to the fifth metal body.

The first metal body and the second metal body may form a first capacitance, the second metal body and the fifth metal body may form a second capacitance, and the first capacitance and the second capacitance may have a ratio, and
the third metal body and the fourth metal body may form a third capacitance, the fourth metal body and the sixth metal body may form a fourth capacitance, and the third capacitance and the fourth capacitance may have a ratio, the ratio between the third capacitance and the fourth capacitance being equal to the ratio between the first capacitance and the second capacitance.

The first capacitance and the second capacitance may be connected in series between a predetermined node.

The second metal body and the fourth metal body may be connected by a plurality of the second metal vias, and the fifth metal body and the sixth metal body may be connected by a plurality of third metal vias, and
each of the plurality of the second metal vias and each of the plurality of third metal vias may be arranged at positions corresponding to each other.

The first metal body and the second metal body may form a first capacitance, and the third metal body and the fourth metal body may form a second capacitance, the first capacitance and the second capacitance being equal to each other.

Each of the first to fourth metal bodies may be formed in a flat plate shape.

A capacitive element configured by stacking, in an insulator, a plurality of layer bodies each including a first metal body and a second metal body formed in a same layer, in which
the first metal bodies of adjacent layers may be connected by a plurality of first metal vias, and the second metal bodies of adjacent layers may be connected by a plurality of second metal vias, and
the plurality of first metal vias and the plurality of second metal vias may be arranged in a lattice pattern.

A display device in which a pixel circuit including the capacitive element according to (1) or (13) is arranged, in which
the pixel circuit may further include:
a drive transistor that drives a light emitting unit; and
a first transistor that writes a signal voltage, and
the capacitive element may have the first metal body connected to a gate electrode of the drive transistor and the second metal body connected to a drain electrode of the drive transistor.

A display device in which a pixel circuit including the capacitive element according to (7) is arranged, in which
the pixel circuit may further include:
a drive transistor that drives a light emitting unit;
a first transistor that writes a signal voltage; and
a second transistor that controls light emission/non-light emission of the light emitting unit, and
the capacitive element may have the first metal body connected to a gate electrode of the drive transistor, a second metal body connected to a source electrode of the drive transistor, and the fifth metal body connected to a node of a fixed potential.

### BRIEF DESCRIPTION OF DRAWINGS

FIG. 1 is a block diagram illustrating a schematic configuration of a display device according to the present embodiment.

FIG. 2 is a diagram illustrating an alignment example of a pixel circuit.

FIG. 3 is a diagram illustrating an example of the pixel circuit.

FIG. 4 is a diagram schematically illustrating a basic configuration example of a capacitive element.

FIG. 5 is a diagram illustrating a more detailed configuration example of the capacitive element.

FIG. 6 is a diagram illustrating a part of a three-dimensional configuration of the capacitive element.

FIG. 7 is a diagram illustrating an example of a configuration of a metal via.

FIG. 8 is a diagram illustrating a part of a three-dimensional configuration of another capacitive element.

FIG. 9A is a diagram illustrating another example of a configuration of a metal via.

FIG. 9B is a diagram illustrating a configuration example in which a metal flat plate is unevenly located.

FIG. 10 is a diagram illustrating a configuration example of a capacitive element that is a comparative example.

FIG. 11 is a block diagram illustrating a schematic configuration of a display device according to a second embodiment.

FIG. 12 is a circuit diagram illustrating an example of a circuit configuration of a pixel.

FIG. 13 is a diagram illustrating a configuration example of a capacitive element according to the second embodiment.

FIG. 14 is a diagram illustrating a part of a three-dimensional configuration of a capacitive element according to the second embodiment.

FIG. 15 is a diagram representing a configuration example of a pixel PIX.

FIG. 16 is a diagram representing another configuration example of the pixel PIX.

FIG. 17 is a diagram representing another configuration example of the pixel PIX.

FIG. 18 is a diagram representing another configuration example of the pixel PIX.

FIG. 19 is a diagram representing another configuration example of the pixel PIX.

FIG. 20 is a diagram representing another configuration example of the pixel PIX.

FIG. 21 is a diagram representing another configuration example of the pixel PIX.

FIG. 22 is a diagram representing another configuration example of the pixel PIX.

FIG. 23 is a diagram representing an example of an external appearance of a head mounted display 110.

FIG. 24 is diagram representing an example of an external appearance of another head mounted display 120.

FIG. 25 is a diagram representing an example of an external appearance of a digital still camera 130 and is a front view.

FIG. 26 is a diagram representing an example of an external appearance of the digital still camera 130 and is a side view.

FIG. 27 is a diagram representing an example of an external appearance of a television apparatus 140.

FIG. 28 is a diagram representing an example of an external appearance of a smartphone 150.

FIG. 29 is a diagram illustrating an example of an inside of a vehicle 200 as viewed from a rear portion of the vehicle.

FIG. 30 is a diagram illustrating an example of the inside of the vehicle 200 as viewed from a left rear portion of the vehicle.

### MODE FOR CARRYING OUT THE INVENTION

Hereinafter, embodiments of a capacitive element and a display device will be described with reference to the drawings. Although main components of the capacitive element and the display device will be mainly described below, the display device possibly include components or functions that are not illustrated or described. The following description is not intended to exclude components and functions that are not illustrated or described.

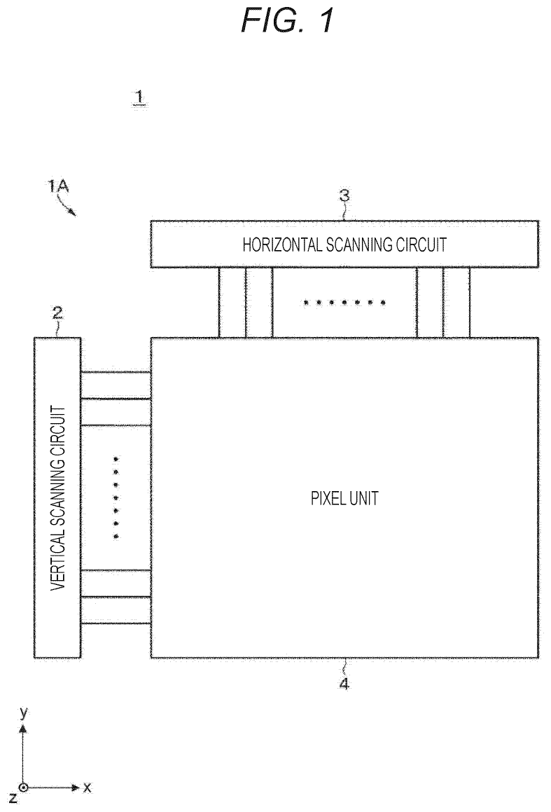

The present technology can be applied to an organic EL display device 1 (display device) including an active matrix-type drive circuit illustrated in FIG. 1. FIG. 1 is a block diagram illustrating a schematic configuration of the display device according to the present embodiment. This display device 1 includes a display panel 1A and a control circuit that controls an operation of the display panel 1A.

Digital image data is supplied to the display device 1 in synchronization with a data synchronization signal. The image data is data that defines, for example, 8-bit gradation levels of pixels of an image to be displayed on the display panel 1A. Furthermore, the synchronization signal is a signal including a vertical synchronization signal, a horizontal synchronization signal, and a dot clock signal. The control circuit generates various control signals on the basis of the synchronization signal and supplies the control signals to the display panel 1A. Furthermore, the control circuit includes a voltage generation circuit. The voltage generation circuit supplies various potentials to the display panel 1A. Moreover, the control circuit generates an image signal on the basis of the image data.

As illustrated in FIG. 1, in the display panel 1A, a vertical scanning circuit (scanning line drive circuit) 2, a horizontal scanning circuit (data line drive circuit) 3, and a pixel unit 4 are formed on a semiconductor substrate, for example, a silicon substrate. A plurality of scanning lines from the vertical scanning circuit 2 is extended in the horizontal direction with respect to the pixel unit 4, and a plurality of data lines from the horizontal scanning circuit 3 is extended in the vertical direction. Pixel circuits are connected in a matrix form to the data lines extending in the vertical direction and the scanning lines extending in the horizontal direction. The display device 1 in FIG. 1 may be a display device for a stationary TV or a personal computer (PC), or may be a display device for portable equipment such as a smartphone.

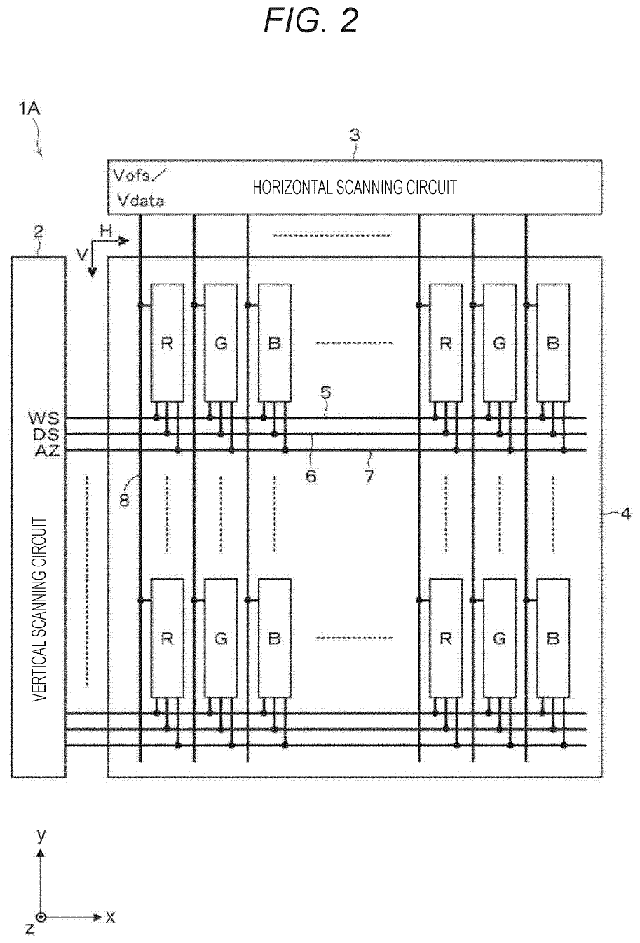

FIG. 2 is a diagram illustrating an alignment example of the pixel circuit. As illustrated in FIG. 2, in the pixel unit 4, with respect to the arrangement of the pixel circuits in a matrix form, three scanning lines (a first scanning line 5, a second scanning line 6, and a third scanning line 7) are wired for every pixel row along the row direction (the arrangement direction of the pixels of the pixel row). Furthermore, with respect to the arrangement of the pixel circuit in a matrix form, a data line 8 is wired for every pixel column along the column direction (an array direction of the pixels of the pixel column). Note that, in the pixel unit 4, as indicated by red (R), blue (B), and green (G), pixel circuits (referred to as subpixels) corresponding to the pixels of three primary colors are provided. These three pixels represents one dot of a color image. Note that the combination of pixels representing one unit (one dot) is not limited to this, and a configuration in which a white (W) pixel for improving luminance is added, or a configuration in which a complementary pixel for expanding a color reproduction range is added may be adopted.

Each of the first scanning lines 5, each of the second scanning lines 6, and each of the third scanning lines 7 are connected to the output end of a corresponding row of the vertical scanning circuit 2. Each of the data lines 8 is connected to the output end of a corresponding column of the horizontal scanning circuit 3.

The vertical scanning circuit 2 includes a shift register or the like. At the time of writing a data signal corresponding to a gradation level to each pixel circuit of the pixel unit 4, the vertical scanning circuit 2 sequentially supplies a write scanning signal WS to each of the first scanning lines 5 to sequentially scan (line-sequentially scan) each pixel circuit of the pixel unit 4 in units of rows. Furthermore, the vertical scanning circuit 2 supplies a first control signal DS to the first scanning line 6 to control light emission/non-light emission (extinction) of the pixel circuit. Moreover, the vertical scanning circuit 2 supplies a second control signal AZ to the third scanning line 7 to control the pixel circuit not to emit light in the non-light emission period. Note that the vertical scanning circuit 2 may perform scanning not only by line-sequential scanning but also by an addressing method.

The horizontal scanning circuit 3 selectively writes, as a write voltage, a signal potential (signal voltage Vdata) of the data signal corresponding to the above-described gradation level and a correction potential (reference voltage Vofs) to each of the data lines 8. That is, the signal voltage Vdata is a voltage corresponding to the gradation level (luminance). The reference voltage Vofs is used at the time when a threshold correction operation is performed.

The data signal output from the horizontal scanning circuit 3 is written to each pixel circuit of the pixel unit 4 via each of the data lines 8 in units of pixel rows selected by scanning by the vertical scanning circuit 2. That is, the horizontal scanning circuit 3 adopts a line-sequential write drive mode in which data signals are written in units of rows (lines).

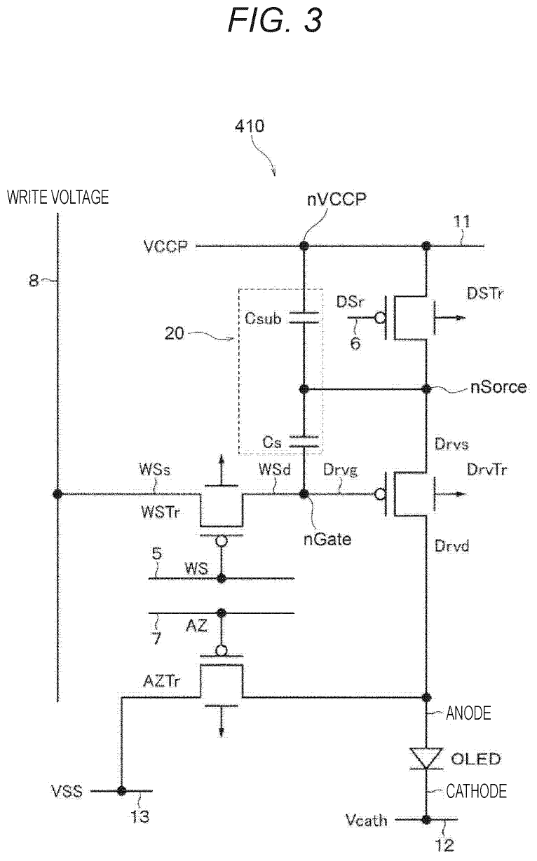

FIG. 3 is a diagram illustrating an example of a pixel circuit 410 of one subpixel. The pixel circuit 410 is connected to the first scanning line 5, the second scanning line 6, and the third scanning line 7 from the vertical scanning circuit 2 and the data line 8 from the horizontal scanning circuit 3. The pixel circuit includes four transistors (a drive transistor DrvTr, a first transistor WSTr, a second transistor DSTr, and a third transistor AZTr), a holding capacitance Cs, an auxiliary capacitance Csub, and an OLED. Note that, here, P-channel transistors are used as these four transistors. That is, the pixel circuit includes Pch4Tr2C. N-channel transistors may also be used. The holding capacitance Cs and the auxiliary capacitance Csub are constituted of a capacitive element 20 described later.

The source of the drive transistor DrvTr is connected to a feeder line 11 via a source node (nSorce) 202 and the transistor DSTr. The drain thereof is connected to the anode of the OLED and controls the current flowing through the OLED. A high-potential power supply (VCCP) is supplied to the feeder line 11. The cathode of the OLED is connected to a power supply line 12 to form a common electrode, which is set to a low potential power supply (Vcath).

In the transistor WSTr (first transistor), the gate is connected to the first scanning line 5, one of the source and the drain, for example, a source WSs is connected to the data line 8, and the other one, for example, a drain WSd is connected to a gate (Drvg) of the drive transistor DrvTr via a gate node (nGate). The transistor WSTr writes a data line potential (gradation potential) to the gate (Drvg) of the drive transistor DrvTr in accordance with the write scanning signal WS.

In the transistor DSTr (second transistor), the gate is connected to the second scanning line 6, one of the source and the drain is connected to the feeder line 11, and the other is connected to the source of the drive transistor DrvTr via the source node (nSource). With this arrangement, the transistor DSTr controls power supply to the drive transistor DrvTr.

In the transistor AZTr (third transistor), the gate is connected to the third scanning line 7, one of the source and the drain is connected to the drain of the drive transistor DrvTr and the anode of the OLED, and the other is connected to a power supply line 13 of a power supply VSS.

The holding capacitance Cs is connected between the gate and the source of the drive transistor DrvTr. That is, the holding capacitance Cs has one end connected to the gate node (nGate) and the other end connected to the source node (nSorce). With this arrangement, the holding capacitance Cs holds a gate-source voltage Vgs of the drive transistor DrvTr.

The auxiliary capacitance Csub is connected between the source of the drive transistor DrvTr and the fixed power supply VCCP. That is, the auxiliary capacitance Csub has one end connected to the source node (nSorce) and the other end connected to a power supply node (nVCCP) 200. With this arrangement, the auxiliary capacitance Csub suppresses fluctuation of the source voltage of the drive transistor DrvTr, and meanwhile, performs threshold correction of the drive transistor DrvTr by capacitive coupling with the holding capacitance Cs.

In the organic EL display device 1 having the above-described configuration, in each pixel circuit, the light emission luminance of the OLED is controlled by the current controlled by the drive transistor DrvTr. Therefore, when a threshold voltage Vth of the drive transistor DrvTr fluctuates in each pixel circuit, the light emission luminance varies for every pixel, and the uniformity of the screen is impaired. Therefore, in the organic EL display device 1, in order to reduce the variation in the light emission luminance caused by the fluctuation in the threshold voltage Vth of the drive transistor DrvTr, the above-described threshold correction is performed along with the line-sequential scanning. In this case, when the ratio between the holding capacitance Cs and the auxiliary capacitance Csub varies, the threshold voltage Vth fluctuates even if the threshold correction is performed. Therefore,
the present embodiment provides a capacitive element that can maintain the ratio between the holding capacitance Cs and the auxiliary capacitance Csub at a design value in order to suppress the fluctuation of the threshold voltage Vth.

### Basic Configuration Example of Capacitive Element (1)

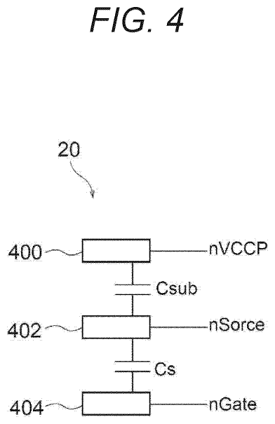

Here, a basic configuration example of the capacitive element 20 will be described with reference to FIGS. 4 to 6. FIG. 4 is a diagram schematically illustrating a basic configuration example of the capacitive element 20. The capacitive element 20 includes a plurality of metal flat plates 400, a plurality of metal flat plates 402, and a plurality of metal flat plates 404.

The plurality of metal flat plates 400 is connected to the power supply node (nVCCP), the plurality of metal flat plates 402 is connected to the source node (nSorce), and the plurality of metal flat plates 404 is connected to the gate node (nGate). As described above, because the plurality of metal flat plates 400 is connected to the same power supply node (nVCCP), the potential thereof is the same. That is, the plurality of metal flat plates 400 is connected in parallel. Similarly, the plurality of metal flat plates 402 is connected to the same source node (nSorce) and connected in parallel. Similarly, the plurality of metal flat plates 404 is connected to the same gate node (nGate) and connected in parallel.

Furthermore, the plurality of metal flat plates 400, the plurality of metal flat plates 402, and the plurality of metal flat plates 404 are separated from each other by an insulator (dielectric). With this arrangement, the auxiliary capacitance Csub is configured between the plurality of metal flat plates 400 and the plurality of metal flat plates 402. Similarly, the holding capacitance Cs is configured between the plurality of metal flat plates 402 and the plurality of metal flat plates 404.

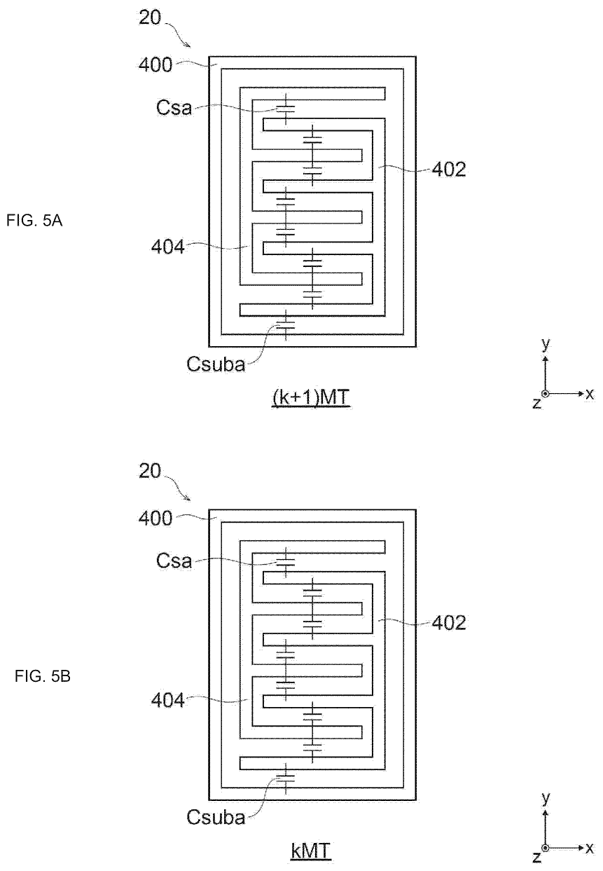

FIG. 5 is a diagram illustrating a more detailed configuration example of the capacitive element 20. The capacitive element 20 includes m layers, and a relationship of m ≥(k+1) is established. Here, m and k are integers of 1 or more. As illustrated in (a) of FIG. 5, a k+1 layer includes the metal flat plate 400, the metal flat plate 402, and the metal flat plate 404. The metal flat plate 400, the metal flat plate 402, and the metal flat plate 404 are included in the same layer indicated by the xy plane. The metal flat plate 400 and the metal flat plate 402 constitute an auxiliary capacitance Csuba. Furthermore, the metal flat plate 402 and the metal flat plate 404 have E-shape structures that fit with each other. As described above, in the same layer, the metal flat plate 402 and the metal flat plate 404 constitute a holding capacitance Csa by a so-called interlocking capacitor. As illustrated in (b) of FIG. 5, a k layer also has the same configuration as the k+1 layer. The auxiliary capacitance Csuba of each layer is added to sum up to the auxiliary capacitance Csub, and the holding capacitance Csa of each layer is added to sum up to the holding capacitance Cs.

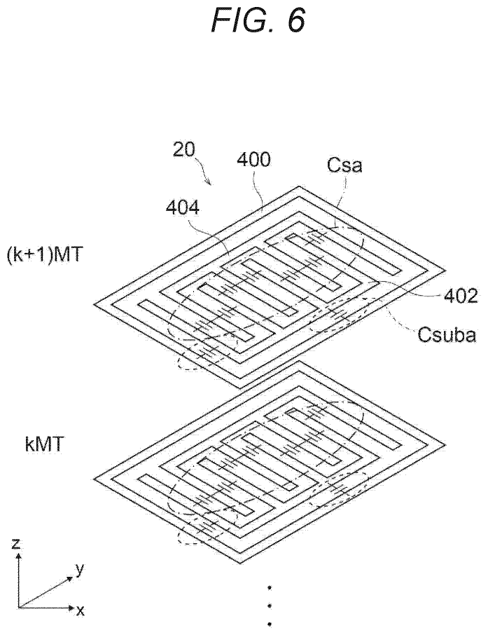

FIG. 6 is a diagram illustrating a part of a three-dimensional configuration of the capacitive element 20. As illustrated in FIG. 6, the metal flat plate 400, the metal flat plate 402, and the metal flat plate 404 of every m layer are respectively stacked so as to overlap in the direction indicated by the Z axis. That is, the metal flat plates 400, the metal flat plates 402, and the metal flat plates 404 respectively connected in parallel is configured linearly in the direction indicated by the Z axis. Furthermore, as described above, an insulating film is formed between each of the layers.

Because the metal flat plates 400 overlapping each other in the Z direction have the same potential, the metal flat plates are not affected by the insulating film formed between the layers. Similarly, the metal flat plates 402 and the metal flat plates 404 are not affected by the insulating film formed between the layers. As described above, because the plurality of metal flat plates 400, the plurality of metal flat plates 402, and the plurality of metal flat plates 404 have the same potential, the metal flat plates are configured not to be affected by the film thickness of the insulating film between the layers. With this arrangement, even if the thickness of the interlayer insulating film between the layers varies, the holding capacitance Cs and the auxiliary capacitance Csub do not vary, and thus, a Csub: Cs ratio is not affected by the film thickness. Moreover, because the holding capacitance Csa and the auxiliary capacitance Csuba are provided for every m layer, a fine structure is achieved, and also, a high capacitance can be achieved.

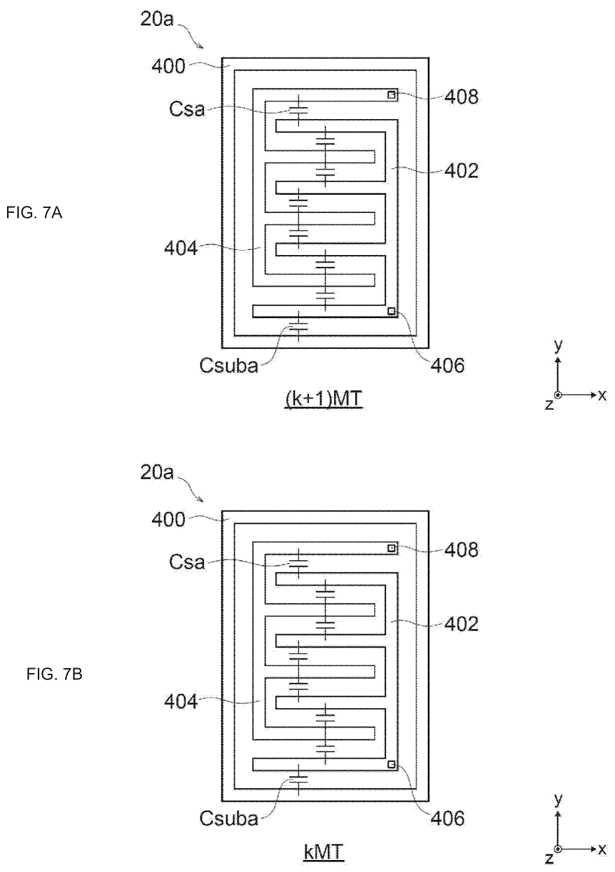

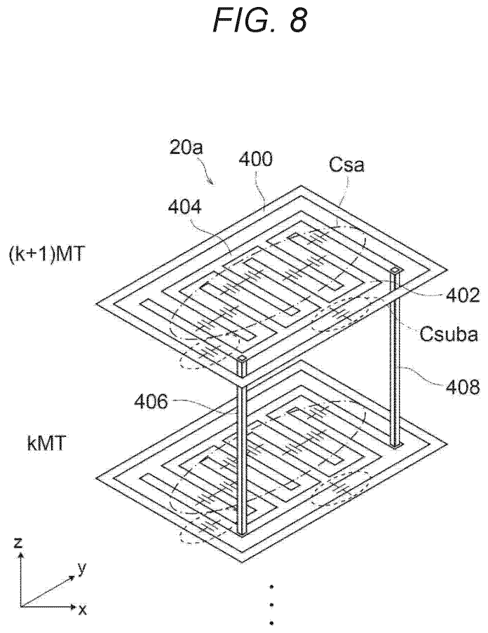

FIG. 7 is a diagram illustrating an example in which metal vias are formed in the metal flat plate 402 and the metal flat plate 404. FIG. 8 is a diagram illustrating a part of a three-dimensional configuration of a capacitive element 20a. The capacitive element 20a illustrated in FIGS. 7 and 8 is different from the capacitive element 20 illustrated in FIGS. 5 and 6 in that a via 406 is formed in the metal flat plate 402 and a via 408 is formed in the metal flat plate 404. The via 204 causes the plurality of metal flat plates 402 included in the m layers to have the same electric potential. Similarly, the via 406 causes the plurality of metal flat plates 404 included in the m layers to have the same electric potential. With this arrangement, the plurality of metal flat plates 402 becomes the same potential as the source node (nSorce) when any one of the metal flat plates 402 is connected to the source node (nSorce). Similarly, the plurality of metal flat plates 404 becomes the same potential as the gate node (nGate) when any one of the metal flat plates 404 is connected to the gate node (nGate).

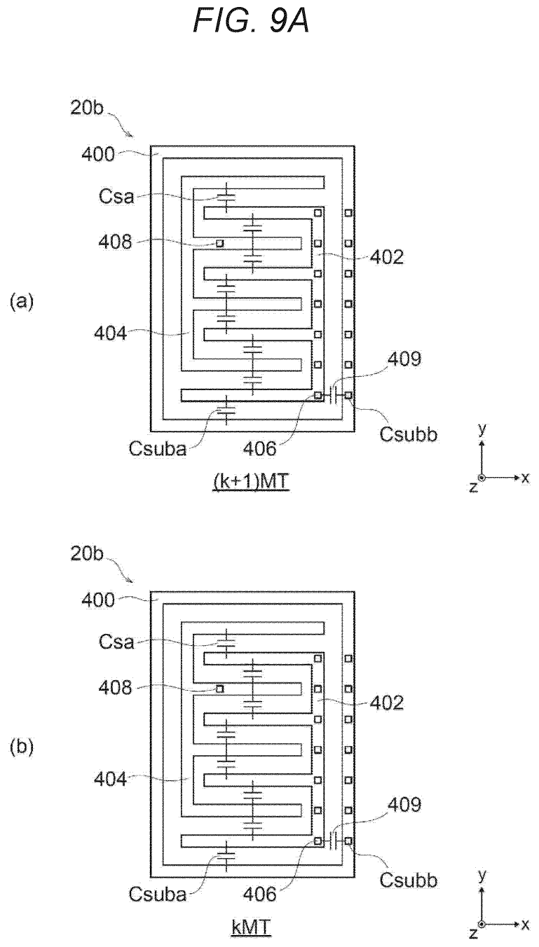

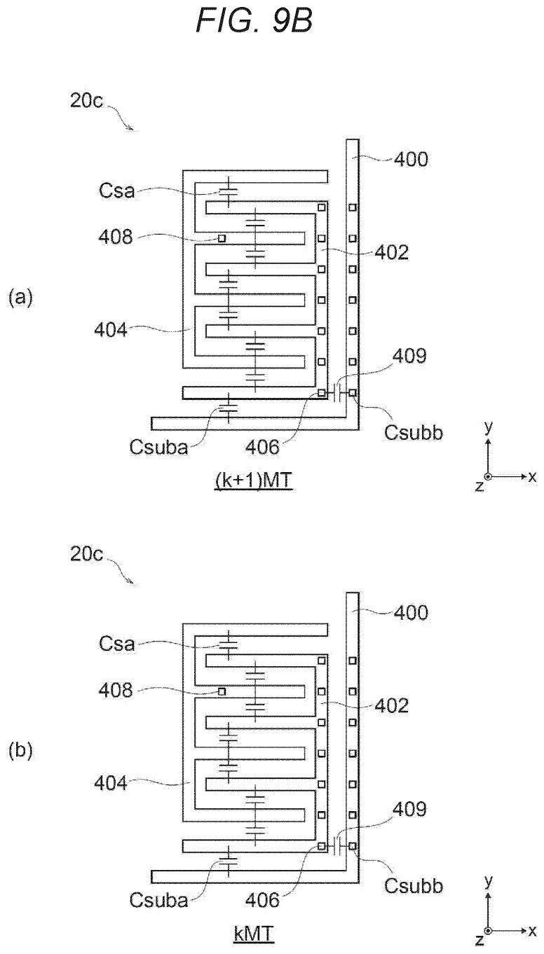

FIG. 9A is a diagram illustrating an example in which metal vias are provided in the metal flat plate 400, the metal flat plate 402, and the metal flat plate 404. A capacitive element 20b illustrated in FIG. 9A is different from the capacitive element 20a illustrated in FIGS. 7 and 8 in that a plurality of vias 406 is formed in the metal flat plate 402 and a plurality of vias 409 is formed in the metal flat plate 400. The plurality of vias 406 and the plurality of vias 409 face each other, and are formed at the shortest distance. With this arrangement, an auxiliary capacitance Csubb can be formed also between the plurality of vias 406 and the plurality of vias 409. The auxiliary capacitances Csuba, Csubb of each layer are added to sum up to the auxiliary capacitance Csub, and the holding capacitance Csa of each layer is added to sum up to the holding capacitance Cs.

On the other hand, the via 408 of the metal flat plate 404 is formed in a range in which capacitive coupling with the metal flat plate 400 and the plurality of vias 409 is suppressed. As can be seen from the above, the auxiliary capacitance Csub, which is the capacitive coupling between the metal flat plate 400 and the metal flat plate 402, is increased, and the capacitive coupling between the metal flat plate 400 and the metal flat plate 404 can be suppressed. In this way, in a case where the capacitances Csub and Cs are to be configured, the target capacitance between the terminals can be adjusted by the arrangement of the vias.

FIG. 9B is a diagram illustrating a configuration example in which the metal flat plate 400 is unevenly located on the metal flat plate 402 side. A capacitive element 20c illustrated in FIG. 9B is different from the capacitive element 20b illustrated FIG. 9A in that the metal flat plate 400 is unevenly located on the metal flat plate 402 side. The metal flat plate 400 and the metal flat plate 404 are separated from each other further in the horizontal plane. With this arrangement, the capacitive coupling between the metal flat plate 400 and the metal flat plate 404 can be suppressed. Note that, even when the capacitive coupling occurs between the metal flat plate 400 and the metal flat plate 404, because a constant potential is applied as an offset to the gate node (nGate) (see FIG. 3), there is no influence on the threshold voltage Vth.

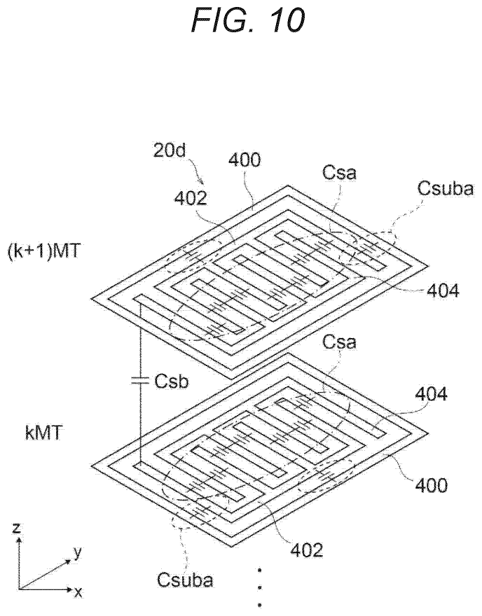

FIG. 10 is a diagram illustrating a configuration example of a capacitive element 20d that is a comparative example. The capacitive element 20d illustrated in FIG. 10 is an example of a metal-oxide-metal (MOM) structure. In the capacitive element 20d, the plurality of metal flat plates 402 is not connected in parallel, and the plurality of metal flat plates 404 is not connected in parallel. Furthermore, the metal flat plate 402 of the (k+1) layer has the same shape as the metal flat plate 404 of the k layer, and is arranged so as to overlap in the Z direction. Similarly, the metal flat plate 404 of the (k+1) layer has the same shape as the metal flat plate 402 of the k layer, and is arranged so as to overlap in the Z direction. With this arrangement, a holding capacitance Csb is also formed between, the metal flat plate 402 and the metal flat plate 404 of the (k+1) layer and the k layer. The auxiliary capacitance Csuba of each layer is added to sum up to the auxiliary capacitance Csub, and the holding capacitances Csa and Csb of each layer are added to sum up to the holding capacitance Cs. However, in the capacitive element 20d of the comparative example, in a case where the film thickness of the insulating film between the (k+1) layer and the n layer varies, the holding capacitance Csb varies, and the Csub: Cs ratio is affected by the film thickness. Therefore, the Vth correction becomes non-uniform in the plane of the pixel unit 4 (see FIG. 2), and so-called surface roughness occurs.

On the other hand, in the capacitive elements 20, 20a, 20b, and 20c according to the present embodiment, the plurality of metal flat plates 402 and the plurality of metal flat plates 404 are made to have the same potential. With this arrangement, even if the thickness of the interlayer insulating film between the layers varies, the holding capacitance Csa and the auxiliary capacitance Csuba in each layer do not vary, and thus, the Csub: Cs ratio is not affected by the film thickness. Therefore, the Vth correction becomes uniform in the plane of the pixel unit 4 (see FIG. 2), and so-called surface roughness is suppressed.

As described above, in the capacitive elements 20, 20a, 20b, and 20c according to the present embodiment, because the plurality of metal flat plates 402 and the plurality of metal flat plates 404 are made to have the same potential, the holding capacitance Cs and the auxiliary capacitance Csub do not vary even when the thickness of the interlayer insulating film varies, and thus, the Csub: Cs ratio is not affected by the film thickness. Moreover, because the holding capacitance Csa and the auxiliary capacitance Csuba (+Csubb) are configured for every m layer, a fine structure is achieved, and also, a high capacitance can be achieved in a state where the ratio Csub: Cs=Csuba (+Csubb): Csa is maintained. With this arrangement, the capacitance difference between the capacitive elements 20, 20a, 20b, and 20c is suppressed.

### Second Embodiment

Regarding the capacitance of the pixel circuit 410 of the display device 1 according to the first embodiment, the holding capacitance Cs and the auxiliary capacitance Csub are connected in series, but there is a difference in a pixel circuit 410a according to the second embodiment that an auxiliary capacitance Csub is not provided. Hereinafter, differences from the display device 1 according to the first embodiment will be described.

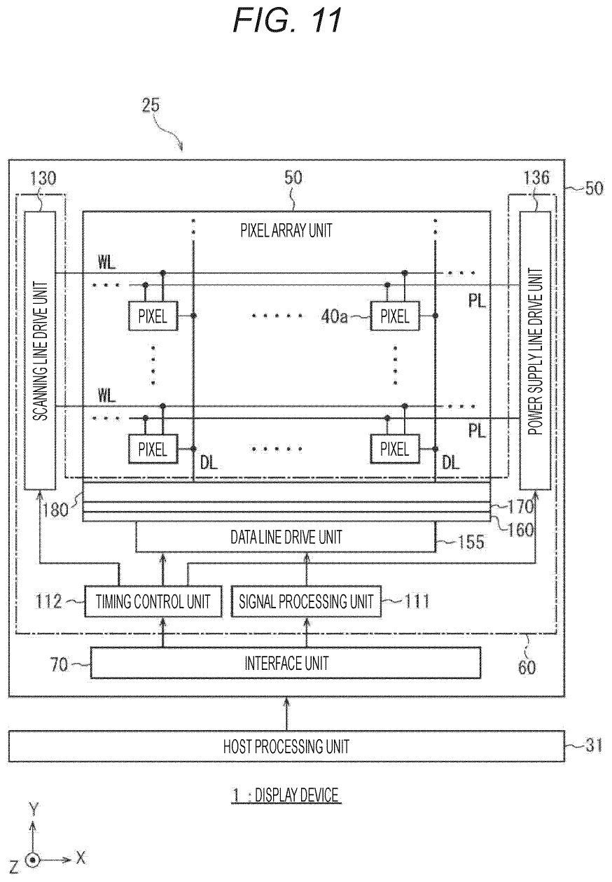

FIG. 11 is a block diagram illustrating a schematic configuration of a display device 1 according to the present embodiment. A screen size of the display device 1 in FIG. 11 is not limited. The display device 1 in FIG. 11 may be a display device for a stationary TV or a personal computer (PC), or may be a display device for portable equipment such as a smartphone. The display device 1 in FIG. 11 includes a display panel unit 25 and a host processing unit 31. The display panel unit 25 is a unit that displays a still image or a moving image on a plurality of pixel circuits 410a arranged on a two-dimensional plane. The host processing unit 31 generates a video signal including pixel data to be displayed on the plurality of pixel circuits 410a of the display panel unit 25 and supplies the video signal to the display panel unit 25. The host processing unit 31 can be constituted of a PC, a server, a workstation, or the like. The display panel unit 25 and the host processing unit 31 transmit and receive video signals in a wired or wireless manner. The host processing unit 31 may be arranged separately from the display panel unit 25, or may be attached to a back surface, or the like, of the display panel unit 25.

The display panel unit 25 includes a pixel array unit 50, a display control unit 60, and an interface unit 70. The pixel array unit 50, the display control unit 60, and the interface unit 70 are provided, for example, on the same substrate. The display control unit 60 and the interface unit 70 may be formed on a substrate by using a semiconductor process technology, or the display control unit 60 or the interface unit 70 formed into a chip may be mounted on a substrate. The display panel unit 25 may be not only a unit including a display screen that allows direct visual recognition, such as a monitor of a TV or a PC, or a smartphone, but also a micro display that allows visual recognition of a projection screen on which an image of the display panel unit 25 is projected. An example of the micro display is an organic light emitting diode (OLED) formed on a single crystal silicon substrate.

The pixel array unit 50 includes the plurality of pixel circuits 410a arranged on a two-dimensional plane. The number of pixel circuits 410a in the pixel array unit 50 is not particularly limited, but may be, for example, 2 k (1920×1080 pixels), 4k (3840×2160 pixels), or other numbers.

The pixel circuits 410a each include a plurality of subpixels that emits light of different colors. For example, the plurality of subpixels includes, for example, red (R), green (G), and blue (B) pixels. Alternatively, the subpixels may include white (W) pixels or pixels of other colors.

The plurality of subpixels in each pixel circuit 410a includes a plurality of self-luminous element that can control light emission individually. Here, the self-luminous element is an element in which an element in a unit of subpixel emits light by itself without a backlight being provided. A typical example of the self-luminous element is an organic EL element. Note that the self-luminous element may be a plasma display element or a field emission display (FED) element. Hereinafter, an example in which an organic EL element is used as a self-luminous element will be mainly described.

The display control unit 60 drives the plurality of pixel circuits 410a in the pixel array unit 50 at a predetermined frame frequency. The frame frequency may be set to be changeable. Note that the frame indicates all the pixels of the pixel array unit 50. The frame frequency is a frequency for driving all of the plurality of pixel circuits 410a in the pixel array unit 50.

The display control unit 60 includes a signal processing unit 111, a timing control unit 112, a scanning line drive unit 131, a power supply line drive unit 136, a data line drive unit 1550, a first wiring part 160, a second wiring part 170, and a switching unit 180.

The signal processing unit 111 generates pixel data on the basis of the video signal transmitted from the host processing unit 31, and supplies the pixel data to the data line drive unit 155. As described later, processing content of the signal processing unit 111 can vary depending on a signal format of the video signal transmitted from the host processing unit 31. A data format of the pixel data transmitted from the signal processing unit 111 to the data line drive unit 155 is different between a case where normal display is performed and a case where thinned display is performed. The thinned display indicates that a part of the pixels are not displayed, and for example, display is performed while a part of the pixels are replaced with black pixels. Furthermore, the signal processing unit 111 may perform existing signal processing such as gamma correction on the video signal transmitted from the host processing unit 31.

The timing control unit 112 generates a control signal for synchronizing the scanning line drive unit 131, the power supply line drive unit 136, and the data line drive unit 155 on the basis of a synchronization signal supplied from the host processing unit 31 or the like, and supplies the control signal to the scanning line drive unit 131, the power supply line drive unit 136, and the data line drive unit 155.

In accordance with the control signal from the timing control unit 112, the scanning line drive unit 131 sequentially supplies scanning signals to the plurality of scanning lines to sequentially select the pixel circuit 410a.

In accordance with a video signal Sdisp2 supplied from the signal processing unit 111 and the control signal supplied from the timing control unit 112, the data line drive unit 155
generates a signal Sig including a pixel voltage Vsig that gives an instruction of light emission luminance of each pixel circuit 410a, and applies the signal Sig to each data line DL.

The first wiring part 160 is connection wiring that connects the data line drive unit 155 to the second wiring part 170. This first wiring part 160 is configured to allow a capacitance difference to be adjusted between pieces of wiring between the data line drive unit 155 and the switching unit 180. Note that details of the first wiring part 160 will be described later.

The second wiring part 170 is, for example, fan-out wiring, and adjusts the number of output terminals of the data line drive unit 155 and the number of switching elements included in the switching unit 180, that is, the number of the data lines DL. For example, the number of output terminals of the data line drive unit 155 and the number of the data lines DL are, for example, 1 to n. n is a natural number including 1, and is, for example, 4.

The switching unit 180 sequentially supplies the signal Sig including the pixel voltage Vsig to the plurality of data lines DL in accordance with the control signal from the timing control unit 112. This switching unit 180 brings the second wiring part 170 and the data line DL into a conductive state or a non-conductive state in accordance with the control signal from the timing control unit 112. For example, the switching unit 180 includes the same number of switching elements as the number of the data lines DL. This switching element includes, for example, a P-channel metal oxide semiconductor (MOS) type thin film transistor (TFT).

The interface unit 70 performs processing of receiving the video signal from the host processing unit 31 and transmitting the video signal to the display control unit 60. In some cases, the interface unit 70 performs parallel/serial data conversion, and then, supplies the pixel data included in the video signal to the display control unit 60. Note that, in the present embodiment, in some cases, a two-dimensional plane of the pixel array unit 50 is referred to as an XY plane, and a Z direction orthogonal to the XY plane is referred to as a vertically upward direction.

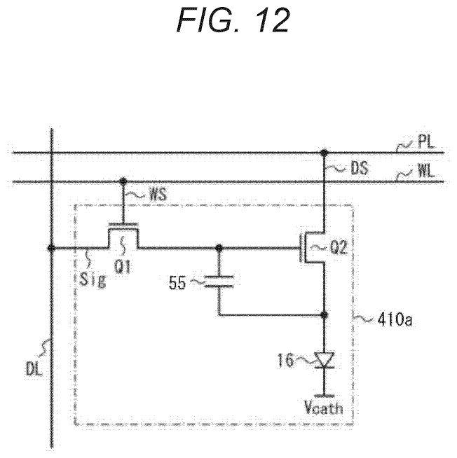

FIG. 12 is a circuit diagram illustrating an example of a circuit configuration of the pixel circuit 410a. The pixel array unit 50 includes a plurality of scanning lines WL and a plurality of power supply lines PL extending in a row direction, and a plurality of data lines DL extending in a column direction. Although not illustrated, one end of the data line DL is connected to the data line drive unit 155 via the switching unit 180, the second wiring part 170, and the first wiring part 160. One end of the scanning line WL is connected to the scanning line drive unit 131, and one end of the power supply line PL is connected to the power supply line drive unit 136. Each pixel circuit 410a is arranged at an intersection of the scanning line WL and the data line DL. The power supply line drive unit 136 controls light emission of the pixel circuits 410a by sequentially supplying the power supply signal DS to the plurality of power supply lines PL in accordance with the control signal supplied from the timing control unit 112. The power supply signal DS transitions between a drive voltage and an initialization voltage. The initialization voltage is a voltage for initializing the pixel circuit 410a, and the drive voltage is a voltage for causing a current Ids to flow through a drive transistor DRTr to cause the self-luminous element to emit light.

The pixel circuit 410a includes a write transistor (first transistor) Q1, a drive transistor Q2, a self-luminous element 16 such as an organic EL element, and a capacitive element 55. In other words, in this example, the pixel circuit 410a has a so-called “2Tr1C” configuration including two transistors (the write transistor Q1, the drive transistor Q2) and one capacitive element 55, but can adopt other configurations. The capacitive element 55 has a capacitance Cs.

Note that details of the capacitive element 55 will be described later.

The write transistor Q1 and the drive transistor Q2 include, for example, N-channel metal oxide semiconductor (MOS) type thin film transistors (TFTs). The write transistor Q1 has the gate connected to the scanning line WL, the source connected to the data line DL, and the drain connected to the gate of the drive transistor Q2 and one end of the capacitive element 55. The drive transistor Q2 has the gate connected to the drain of the write transistor Q1 and one end of the capacitive element 55, the drain connected to the power supply line PL, and the source connected to the other end of the capacitive element 55 and the anode of the self-luminous element 16.

The capacitive element 55 has one end connected to the gate or the like of the drive transistor Q2 and the other end connected to the source or the like of the drive transistor Q2. The capacitive element 55 has a capacitance Cs. The self-luminous element 16 is a light emitting element configured by using an organic EL device, and has the anode connected to the source of the drive transistor Q2 and the other end of the capacitive element 55, and the cathode is supplied with a voltage Vcath that is a DC voltage. This self-luminous element 16 emits white light. In other words, in this example, the pixel circuit 410a is provided with the self-luminous element 16 that emits white light and color filters to generate red (R), green (G), and blue (B) light, respectively. Color filters of colors other than RGB may be provided, and subpixels of four or more colors may constitute one pixel. Note that, as the self-luminous element 16, three or more types of self-luminous elements 16 that emit light in different emission colors such as red, green, and blue may be provided in the subpixel in the pixel circuit 410a. In this case, the color filters are not necessarily required.

The display control unit 60 according to the present embodiment writes the pixel voltage Vsig to the capacitive element 55 of each pixel circuit 410a within one horizontal period. With this arrangement, the self-luminous element 16 emits light with luminance corresponding to the written pixel voltage Vsig.

The display control unit 60 can thin out and drive the plurality of pixel circuits 410a in consecutive individual frames, where the pixel circuits 410a to be thinned out are different for every frame. Furthermore, the display control unit 60 can drive all of the plurality of pixel circuits 410a in a plurality of consecutive frames. In this manner, the display control unit 60 can drive a part of the pixel circuits 410a different for every frame and drive all of the plurality of pixel circuits 410a in the plurality of frames.

### Basic Configuration Example of Capacitive Element (2)

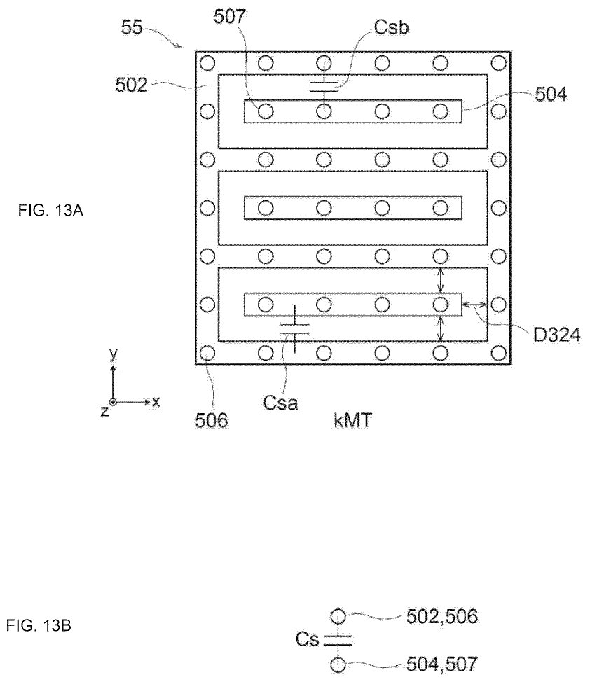

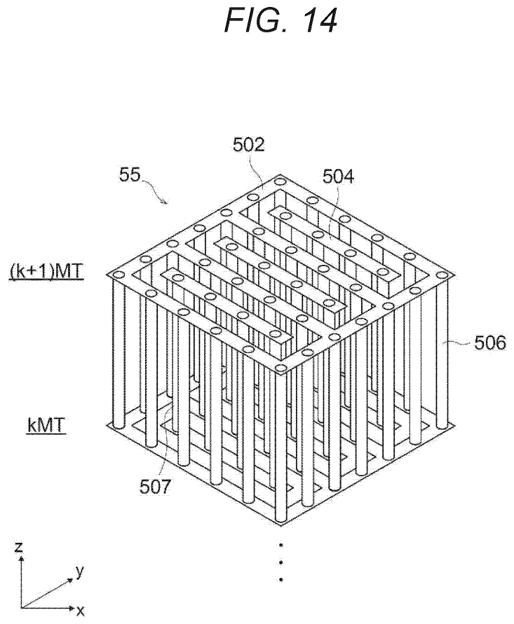

Here, a basic configuration example of the capacitive element 55 according to the present embodiment will be described with reference to FIGS. 13 and 14. FIG. 13 is a diagram illustrating a configuration example of the capacitive element 55. FIG. 13 (a) is a diagram illustrating a configuration example of the capacitive element 55 in the same layer. The capacitive element 55 includes a plurality of layers (m layers). The capacitive element 55 in the same layer includes a metal flat plate 502, a plurality of metal flat plates 504, a plurality of vias 506, and a plurality of vias 507. That is, the metal flat plate 502 and the plurality of metal flat plates 504 are included in the same layer indicated by the xy plane. Furthermore, the metal flat plate 502 is connected to the gate of the drive transistor Q2, and the plurality of the metal flat plates 504 is connected to the source of the drive transistor Q2.

The plurality of vias 506 and the plurality of vias 507 are arranged in a lattice pattern. With this arrangement, the via 506 and the via 507 adjacent to each other are configured at a shortest distance D324, and connect the metal flat plates 502 and the plurality of metal flat plates 504 of different layers.

FIG. 13(b) is a diagram schematically illustrating a basic configuration example of the capacitive element 55. The capacitive element 55 includes a plurality of layers (m layers). As described above, each phase has the metal flat plate 502 and the plurality of metal flat plates 504 in the same layer. The metal flat plates 502 are connected to the gate of the drive transistor Q2 (see FIG. 12) and the other end is connected to the source or the like of the drive transistor Q2. With this arrangement, the metal flat plate 502 and the plurality of metal flat plates 504 in the same layer constitute a capacitance Csa that is a part of the capacitance Cs. Furthermore, the via 506 and the via 507 adjacent to each other between the layers constitute a capacitance Csb which is a part of the capacitive element Cs. The adjacent vias 506 and 507 are configured at the shortest distance D324, and thus, the capacitance Cs can be increased. By adding up these capacitances Csa and Csb in all the layers, the capacitance Cs which is a design value is obtained. Note that the capacitance Csb is configured while receiving a larger influence of the distance to the insulating film from between the via 506 and the via 507 in the same xy plane. In other words, the capacitance Csb is configured so as not to be substantially affected by the thickness of the insulating film in the Z direction.

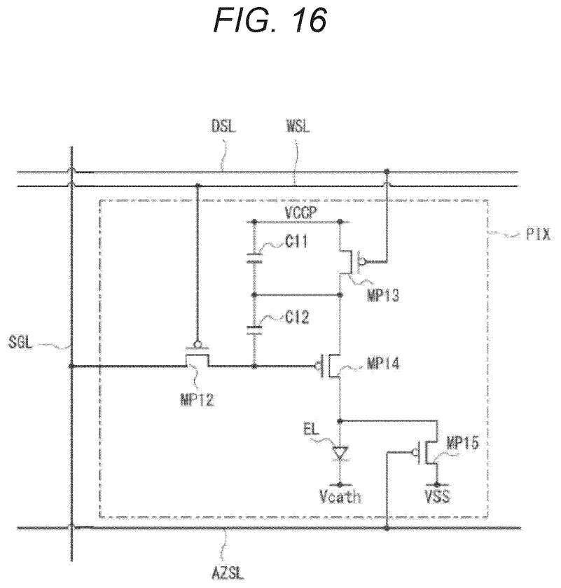

FIG. 14 is a diagram illustrating a part of a three-dimensional configuration of the capacitive element 55. As illustrated in FIG. 16, the metal flat plates 502 and the plurality of metal flat plates 504 of every m layer are stacked so as to respectively overlap in the direction indicated by the Z axis. That is, the metal flat plates 502 and the plurality of metal flat plates 504 that are respectively connected in parallel are configured linearly in the direction indicated by the Z axis. Furthermore, an insulating film is formed between each of the layers.

Because the metal flat plates 502 overlapping each other in the Z direction have the same potential, the metal flat plates are not affected by the insulating film formed between the layers. Similarly, the plurality of metal flat plates 504 is not affected by the insulating film formed between the layers. As described above, because the plurality of metal flat plates 502 and the plurality of metal flat plates 504 have the same potential, the metal flat plates are configured not to be affected by the film thickness of the insulating film between the layers. With this arrangement, even if the thickness of the interlayer insulating film between the layers varies, the capacitances Csa and Csb are not affected by the film thickness. Furthermore, by having the vias 506 and 507 adjacent to each other between the layers, the capacitance Cs can be increased.

The capacitive elements 55 according to the present embodiment is configured such that the plurality of metal flat plates 502 and the plurality of metal flat plates 504 are made to have the same potential. With this arrangement, even if the thickness of the insulating film between the layers varies, the capacitance Cs can be configured not to be affected by the film thickness, and thus, the capacitance difference of the capacitive element 55 is suppressed. Furthermore, the plurality of vias 506 and the plurality of vias 507 are arranged in a lattice pattern. With this arrangement, the adjacent vias 506 and 507 are configured at the shortest distance D324, and thus, the capacitance Cs can be increased.

### Configuration Example of Pixel Circuit

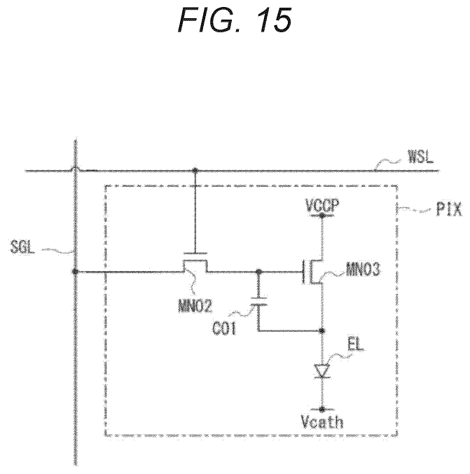

The pixel circuit 410 and the pixel circuit 410a of the display device 1 according to the first embodiment and the second embodiment can include a pixel PIX illustrated in FIGS. 15 to 22.

FIG. 15 is a diagram representing a configuration example of the pixel PIX. The pixel PIX includes a capacitor C01, transistors MN02 to MN03, and a light emitting element EL. The transistors MN02 to MN03 are N-type metal oxide semiconductor field effect transistors (MOSFETs). The transistor MN02 has the gate connected to a control line WSL, the drain connected to a signal line SGL, and the source connected to the gate of the transistor MN03 and the capacitor C01. The capacitor C01 has one end connected to the source of the transistor MN02 and the gate of the transistor MN03, and the other end connected to the source of the transistor MN03 and the anode of the light emitting element EL. The transistor MN03 has the gate connected to the source of the transistor MN02 and one end of the capacitor C01, the drain connected to a power supply line VCCP, and the source connected to the other end of the capacitor C01 and the anode of the light emitting element EL. The light emitting element EL is, for example, an organic EL light emitting element, has the anode connected to the source of the transistor MN03 and the other end of the capacitor C01, and the cathode connected to a power supply line Vcath.

The capacitor C01 has a configuration that is the same as, for example, the capacitive element 55 illustrated in FIGS. 13 and 14. At this time, in the capacitive element 55, the plurality of metal flat plates 502 is connected to the source of the transistor MN02 and the gate of the transistor MN03, the plurality of metal flat plates 504 is connected to the source of the transistor MN03 and the anode of the light emitting element EL, and the capacitor C01 is constituted.

With this configuration, in the pixel PIX, by the transistor MN02 being brought into the on state, a voltage between both ends of the capacitor C01 is set on the basis of the pixel signal supplied from the signal line SGL. The transistor MN03 causes a current corresponding to the voltage between both ends of the capacitor C01 to flow through the light emitting element EL. The light emitting element EL emits light on the basis of the current supplied from the transistor MN03. In this manner, the pixel PIX emits light with luminance corresponding to the pixel signal.

FIG. 16 is a diagram representing another configuration example of the pixel PIX. This pixel PIX includes capacitors C11 and C12, transistors MP12 to MP15, and the light emitting element EL. The transistors MP12 to MP15 are P-type MOSFETs. The transistor MP12 has the gate connected to the control line WSL, the source connected to the signal line SGL, and the drain connected to the gate of the transistor MP14 and the capacitor C12. The capacitor C11 has one end connected to the power supply line VCCP, and the other end connected to the capacitor C12, the drain of the transistor MP13, and the source of the transistor MP14. The capacitor C12 has one end connected to the other end of the capacitor C11, the drain of the transistor MP13, and the source of the transistor MP14, and the other end connected to the drain of the transistor MP12 and the gate of the transistor MP14. The transistor MP13 has the gate connected to a control line DSL, the source connected to the power supply line VCCP, and the drain connected to the source of the transistor MP14, the other end of the capacitor C11, and one end of the capacitor C12. The transistor MP14 has the gate connected to the drain of the transistor MP12 and the other end of the capacitor C12, the source connected to the drain of the transistor MP13, the other end of the capacitor C11, and one end of the capacitor C12, and the drain connected to the anode of the light emitting element EL and the source of the transistor MP 15. The transistor MP15 has the gate connected to a control line AZSL, the source connected to the drain of the transistor MP14 and the anode of the light emitting element EL, and the drain connected to a power supply line VSS.

The capacitors C11 and C12 each have a configuration that is the same as, for example, the capacitive element 20a illustrated in FIGS. 7 and 8. At this time, in the capacitive element 20a, the plurality of metal flat plates 400 is connected to the power supply line VCCP, and the plurality of metal flat plates 404 is connected to the gate of the transistor MP14. The plurality of metal flat plates 402 is connected to the source of the transistor MP14 to constitute the capacitors C11 and C12.

With this configuration, in the pixel PIX, by the transistor MP12 being brought into the on state, a voltage between both ends of the capacitor C12 is set on the basis of the pixel signal supplied from the signal line SGL. The transistor MP13 is turned on and off on the basis of the signal of the control line DSL. The transistor MP14 causes a current corresponding to the voltage between both ends of the capacitor C12 to flow through the light emitting element EL during the period in which the transistor MP13 is in the on state. The light emitting element EL emits light on the basis of the current supplied from the transistor MP14. In this manner, the pixel PIX emits light with luminance corresponding to the pixel signal. The transistor MP15 is turned on and off on the basis of the signal of the control line AZSL. During the period in which the transistor MP15 is in the on state, a voltage of the anode of the light emitting element EL is initialized by being set to the voltage of the power supply line VSS.

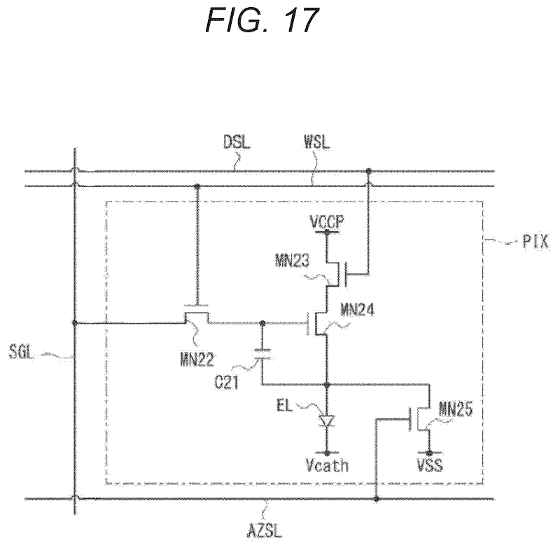

FIG. 17 is a diagram representing another configuration example of the pixel PIX. The pixel PIX includes a capacitor C21, transistors MN22 to MN25, and the light emitting element EL. The transistors MN22 to MN25 are N-type MOSFETs. The transistor MN22 has the gate connected to the control line WSL, the drain connected to the signal line SGL, and the source connected to the gate of the transistor MN24 and the capacitor C21. The capacitor C21 has one end connected to the source of the transistor MN22 and the gate of the transistor MN24, and the other end connected to the source of the transistor MN24, the drain of the transistor MN25, and the anode of the light emitting element EL. The transistor MN23 has the gate connected to the control line DSL, the drain connected to the power supply line VCCP, and the source connected to the drain of the transistor MN24. The transistor MN24 has the gate connected to the source of the transistor MN22 and one end of the capacitor C21, the drain connected to the source of the transistor MN23, and the source connected to the other end of the capacitor C21, the drain of the transistor MN25, and the anode of the light emitting element EL. The transistor MN25 has the gate connected to the control line AZSL, the drain connected to the source of the transistor MN24, the other end of the capacitor C21, and the anode of the light emitting element EL, and the source connected to the power supply line VSS.

The capacitor C21 has a configuration that is the same as, for example, the capacitive element 55 illustrated in FIGS. 13 and 14. At this time, in the capacitive element 55, the plurality of metal flat plates 502 is connected to the gate of the transistor MN24, the plurality of metal flat plates 504 is connected to the drain of the transistor MN24 and the anode of the light emitting element EL, and the capacitor C21 is constituted.

With this configuration, in the pixel PIX, as a result of the transistor MN22 being brought into the on state, a voltage between both ends of the capacitor C21 is set on the basis of the pixel signal supplied from the signal line SGL. The transistor MN23 is turned on and off on the basis of the signal of the control line DSL. The transistor MN24 causes a current corresponding to the voltage between both ends of the capacitor C21 to flow through the light emitting element EL during the period in which the transistor MN23 is in the on state. The light emitting element EL emits light on the basis of the current supplied from the transistor MN24. In this manner, the pixel PIX emits light with luminance corresponding to the pixel signal. The transistor MN25 is turned on and off on the basis of the signal of the control line AZSL. During the period in which the transistor MN25 is in the on state, a voltage of the anode of the light emitting element EL is initialized by being set to the voltage of the power supply line VSS.

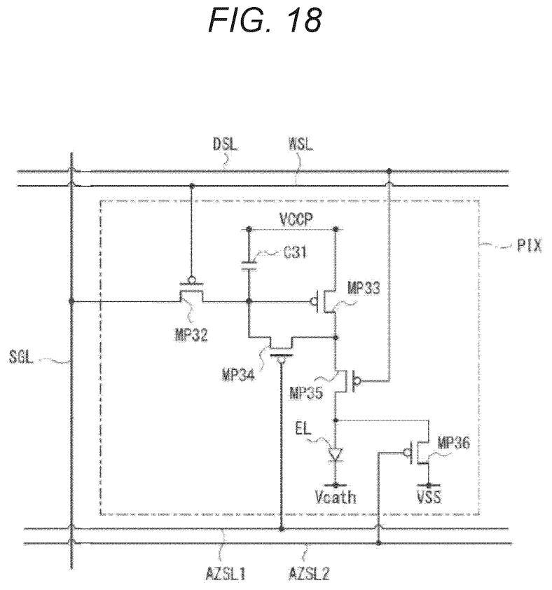

FIG. 18 is a diagram representing another configuration example of the pixel PIX. The pixel PIX includes a capacitor C31, transistors MP32 to MP36, and the light emitting element EL. The transistors MP32 to MP36 are P-type MOSFETs. The transistor MP32 has the gate connected to the control line WSL, the source connected to the signal line SGL, and the drain connected to the gate of the transistor MP33, the drain of the transistor MP34, and the capacitor C31. The capacitor C31 has one end connected to the power supply line VCCP, and the other end connected to the drain of the transistor MP32, the gate of the transistor MP33, and the drain of the transistor MP34. The transistor MP34 has the gate connected to a control line AZSLI, the source connected to the drain of the transistor MP33 and the source of the transistor MP35, and the drain connected to the drain of the transistor MP32, the gate of the transistor MP33, and the other end of the capacitor C31. The transistor MP35 has the gate connected to the control line DSL, the source connected to the drain of the transistor MP33 and the source of the transistor MP34, and the drain connected to the source of the transistor MP36 and the anode of the light emitting element EL. The transistor MP36 has the gate connected to a control line AZSL2, the source connected to the drain of the transistor MP35 and the anode of the light emitting element EL, and the drain connected to the power supply line VSS.

The capacitor C31 has a configuration that is the same as, for example, the capacitive element 55 illustrated in FIGS. 13 and 14. At this time, in the capacitive element 55, the plurality of metal flat plates 502 is connected to the power supply line VCCP, and the plurality of metal flat plates 504 is connected to the gate of the transistor MP33, and the capacitor C31 is constituted.

With this configuration, in the pixel PIX, by the transistor MP32 being brought into the on state, a voltage between both ends of the capacitor C31 is set on the basis of the pixel signal supplied from the signal line SGL. The transistor MP35 is turned on and off on the basis of the signal of the control line DSL. The transistor MP33 causes a current corresponding to the voltage between both ends of the capacitor C31 to flow to the light emitting element EL during the period in which the transistor MP35 is in the on state. The light emitting element EL emits light on the basis of the current supplied from the transistor MP33. In this manner, the pixel PIX emits light with luminance corresponding to the pixel signal. The transistor MP34 is turned on and off on the basis of the signal of the control line AZSL1. The drain and the gate of the transistor MP34 are connected to each other during the period in which the transistor MP33 is in the on state. The transistor MP36 is turned on and off on the basis of the signal of the control line AZSL2. During the period in which the transistor MP36 is in the on state, the voltage of the anode of the light emitting element EL is initialized by being set to the voltage of the power supply line VSS.

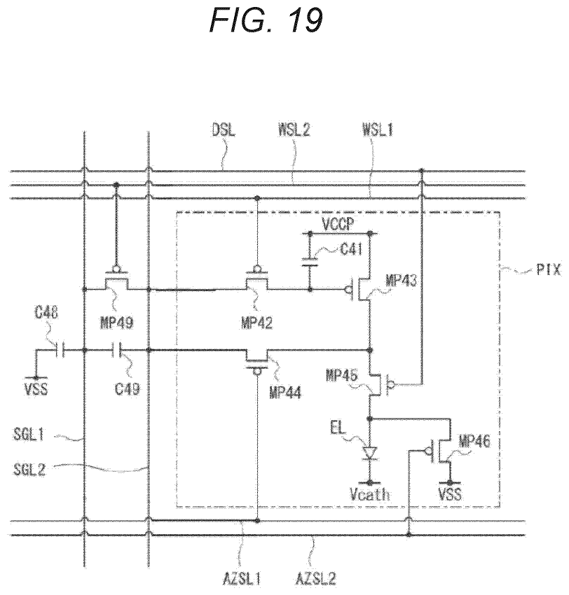

FIG. 19 is a diagram representing another configuration example of the pixel PIX. A capacitor C48 has one end connected to a signal line SGL1, and the other end connected to the power supply line VSS. A capacitor C49 has one end connected to the signal line SGL1, and the other end connected to a signal line SGL2. A transistor MP49 is a P-type MOSFET, and has the gate connected to a control line WSL2, the source connected to the signal line SGL1, and the drain connected to the signal line SGL2.

The pixel PIX includes a capacitor C41, transistors MP42 to MP46, and the light emitting element EL. The transistors MP42 to MP46 are P-type MOSFETs. The transistor MP42 has the gate connected to a control line WSL1, the source connected to the signal line SGL2, and the drain connected to the gate of the transistor MP43 and the capacitor C41. The capacitor 41 has one end connected to the power supply line VCCP, and the other end connected to the drain of the transistor MP42 and the gate of the transistor MP43. The transistor MP43 has the gate connected to the drain of the transistor MP42 and the other end of the capacitor C41, the source connected to the power supply line VCCP, and the drain connected to the sources of the transistors MP44 and MP45. The transistor MP44 has the gate connected to the control line AZSL1, the source connected to the drain of the transistor MP43 and the source of the transistor MP45, and the drain connected to the signal line SGL2. The transistor MP45 has the gate connected to the control line DSL, the source connected to the drain of the transistor MP43 and the source of the transistor MP44, and the drain connected to the source of the transistor MP46 and the anode of the light emitting element EL. The transistor MP46 has the gate connected to the control line AZSL2, the source connected to the drain of the transistor MP45 and the anode of the light emitting element EL, and the drain connected to the power supply line VSS.

The capacitor C41 has a configuration that is the same as, for example, the capacitive element 55 illustrated in FIGS. 13 and 14. At this time, in the capacitive element 55, the plurality of metal flat plates 502 is connected to the power supply line VCCP, and the plurality of metal flat plates 504 is connected to the gate of the transistor MP43, and the capacitor C31 is constituted.

With this configuration, in the pixel PIX, by the transistor MP42 being brought into the on state, a voltage between both ends of the capacitor C41 is set on the basis of the pixel signal supplied from the signal line SGL1 via the capacitor C49. The transistor MP45 is turned on and off on the basis of the signal of the control line DSL. The transistor MP43 causes a current corresponding to the voltage between both ends of the capacitor C41 to flow through the light emitting element EL during the period in which the transistor MP45 is in the on state. The light emitting element EL emits light on the basis of the current supplied from the transistor MP43. In this manner, the pixel PIX emits light with luminance corresponding to the pixel signal. The transistor MP44 is turned on and off on the basis of the signal of the control line AZSL1. During the period in which the transistor MP44 is in the on state, the drain of the transistor MP43 and the signal line SGL2 are connected to each other. The transistor MP46 is turned on and off on the basis of the signal of the control line AZSL2. During the period in which the transistor MP46 is in the on state, the voltage of the anode of the light emitting element EL is initialized by being set to the voltage of the power supply line VSS.

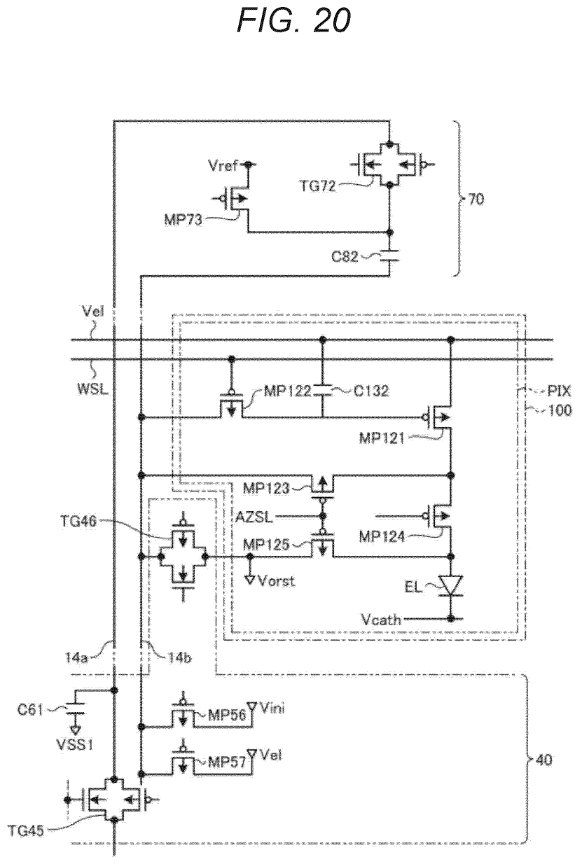

FIG. 20 is a diagram representing another configuration example of the pixel PIX. A plurality of the pixels PIX is provided in a matrix in a display area 100, and the display area 100 is provided between a first control unit 40 and a second control unit 70.

The first control unit 40 includes transmission gates TG45 and TG46, transistors MP56 and MP57, and a capacitor C61. The transistors MP56 and MP57 are P-type MOSFETs. A pixel signal is supplied to the input end of the transmission gate TG45, and the output end of the transmission gate TG45 is connected to one end of a signal line 14a. The input end of the transmission gate TG46 is connected to a signal line 14b, and the output end of the transmission gate TG46 is connected to a power supply line Vorst. The capacitor C61 has one end connected to the signal line 4a, and the other end connected to a power supply line VSS1. The transistor MP56 has the gate connected to a control line INIL, the source connected to a power supply line Vini, and the drain connected to the signal line 14b. The transistor MP57 has the gate connected to a control line ELL, the source connected to a power supply line Ve1, and the drain connected to the signal line 14b.

The second control unit 70 includes a transmission gate TG72, a transistor MP73, and a capacitor C82. The transistor MP73 is a P-type MOSFET. The transmission gate TG72 has the input end connected to the other end of the signal line 14a, and the output end connected to the drain of the transistor MP73 and one end of the capacitor C82. The transistor MP73 has the gate connected to a control line REFL, the source connected to a power supply line Vref, and the drain connected to the output end of the transmission gate TG72 and one end of the capacitor C82. The capacitor C82 has one end connected to the output end of the transmission gate TG72 and the drain of the transistor MP73, and the other end connected to one end of the signal line 14b.

The pixel PIX includes a capacitor C132, transistors MP121 to MP125, and the light emitting element EL. The transistors MP121 to MP125 are P-type MOSFETs. The transistor MP122 has the gate connected to the control line WSL, the source connected to the signal line 14b, and the drain connected to the gate of the transistor MP121 and the capacitor C132. The capacitor C132 has one end connected to the power supply line Vel, and the other end connected to the drain of the transistor MP122 and the gate of the transistor MP121. The transistor MP121 has the gate connected to the drain of the transistor MP122 and the other end of the capacitor C132, the source connected to the power supply line Ve1, and the drain connected to the sources of the transistors MP123 and MP124. The transistor MP123 has the gate connected to the control line AZSL, the source connected to the drain of the transistor MP121 and the source of the transistor MP124, and the drain connected to the signal line 14b. The transistor MP124 has the gate connected to the control line DSL, the source connected to the drain of the transistor MP121 and the source of the transistor MP123, and the drain connected to the drain of the transistor MP125 and the anode of the light emitting element 130. The transistor MP125 has the gate connected to the control line AZSL, the source connected to the power supply line Vorst, and the drain connected to the drain of the transistor MP124 and the anode of the light emitting element 130.

The capacitor C132 has a configuration that is the same as, for example, the capacitive element 55 illustrated in FIGS. 13 and 14. At this time, in the capacitive element 55, the plurality of metal flat plates 502 is connected to the power supply line VCCP, and the plurality of metal flat plates 504 is connected to the gate of the transistor MP121, and the capacitor C132 is constituted.

With this configuration, in the pixel PIX, by the transistor MP122 being brought into the on state, a voltage between both ends of the capacitor C132 is set on the basis of the pixel signal supplied via the transmission gate TG45, the signal line 14a, the transmission gate TG72, the capacitor C82, and the signal line 14b. The transistor MP124 is turned on and off on the basis of the signal of the control line DSL. The transistor MP121 causes a current corresponding to the voltage between both ends of the capacitor C132 to flow through the light emitting element EL during the period in which the transistor MP124 is in the on state. The light emitting element EL emits light on the basis of the current supplied from the transistor MP121. In this manner, the pixel PIX emits light with luminance corresponding to the pixel signal. The transistor MP123 and MP125 are turned on and off on the basis of the signal of the control line AZSL. During the period in which the transistor MP123 is in the on state, the drain of the transistor MP121 and the source of the transistor MP124 are connected to the signal line 14b. During the period in which the transistor MP125 is in the on state, a voltage of the anode of the light emitting element EL is initialized by being set to the voltage of the power supply line Vorst. Furthermore, the transistor MP56 is turned on and off on the basis of the signal of the control line INIL, the transistor MP57 is turned on and off on the basis of the signal of the control line ELL, and the transistor MP73 is turned on and off on the basis of the signal of the control line REFL. When the transistor MP56 is brought into the on state, the signal line 14b is set to the voltage of the power supply line Vini, and when the transistor MP57 is brought into the on state, the signal line 14b is set to the voltage of the power supply line Vel. When the transistor MP73 is brought into the on state, one end of the capacitor C82 is initialized by being set to the voltage of the power supply line Vref.

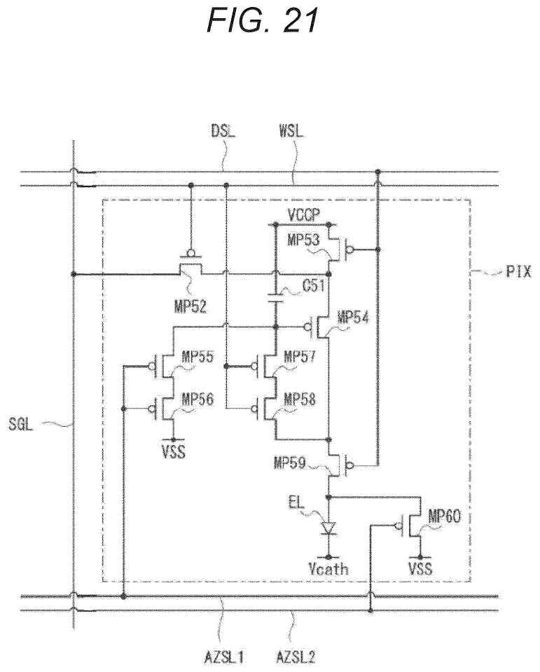

FIG. 21 is a diagram representing another configuration example of the pixel PIX. The pixel PIX includes a capacitor C51, transistors MP52 to MP60, and the light emitting element EL. The transistors MP52 to MP60 are P-type MOSFETS. The transistor MP52 has the gate connected to the control line WSL, the source connected to the signal line SGL, and the drain connected to the drain of the transistor MP53 and the source of the transistor MP54. The transistor MP53 has the gate connected to the control line DSL, the source connected to the power supply line VCCP, and the drain connected to the drain of the transistor MP52 and the source of the transistor MP54. The transistor MP54 has the gate connected to the source of the transistor MP55, the drain of the transistor MP57, and the capacitor C51, the source connected to the drains of the transistors MP52 and MP53, and the drain connected to the sources of the transistors MP58 and MP59. The capacitor C51 has one end connected to the power supply line VCCP, and the other end connected to the gate of the transistor MP54, the source of the transistor MP55, and the drain of the transistor MP57. The capacitor C51 may include two capacitors connected in parallel to each other. The transistor MP55 has the gate connected to the control line AZSLI, the source connected to the gate of the transistor MP54, the drain of the transistor MP57, and the other end of the capacitor C51, and the drain connected to the source of the transistor MP56. The transistor MP56 has the gate connected to the control line AZSL1, the source connected to the drain of the transistor MP55, and the drain connected to the power supply line VSS. The transistor MP57 has the gate connected to the control line WSL, the drain connected to the gate of the transistor MP54, the source of the transistor MP55, and the other end of the capacitor C51, and the source connected to the drain of the transistor MP58. The transistor MP58 has the gate connected to the control line WSL, the drain connected to the source of the transistor MP57, and the source connected to the drain of the transistor MP54 and the source of the transistor MP59. The transistor 59 has the gate connected to the control line DSL, the source connected to the drain of the transistor MP54 and the source of the transistor MP58, and the drain connected to the source of the transistor MP60 and the anode of the light emitting element EL. The transistor MP60 has the gate connected to the control line AZSL2, the source connected to the drain of the transistor MP59 and the anode of the light emitting element EL, and the drain connected to the power supply line VSS.

The capacitor C51 has a configuration that is the same as, for example, the capacitive element 55 illustrated in FIGS. 13 and 14. At this time, in the capacitive element 55, the plurality of metal flat plates 502 is connected to the power supply line VCCP, and the plurality of metal flat plates 504 is connected to the gate of the transistor MP54, and the capacitor C51 is constituted.

With this configuration, in the pixel PIX, by the transistors MP52, MP54, MP58, and MP57 being brought into the on state, a voltage between both ends of the capacitor C51 is set on the basis of the pixel signal supplied from the signal line SGL. The transistors MP53 and MP59 are turned on and off on the basis of the signal of the control line DSL. The transistor MP54 causes a current corresponding to the voltage between both ends of the capacitor C51 to flow through the light emitting element EL during the period in which the transistors MP53 and MP59 are in the on state. The light emitting element EL emits light on the basis of the current supplied from the transistor MP 54. In this manner, the pixel PIX emits light with luminance corresponding to the pixel signal. The transistors MP55 and MP56 are turned on and off on the basis of the signal of the control line AZSL1. During a period in which the transistors MP55 and MP56 are in the on state, a voltage of the gate of the transistor MP54 is initialized by being set to the voltage of the power supply line VSS. The transistor MP60 is turned on and off on the basis of the signal of the control line AZSL2. During a period in which the transistor MP60 is in the on state, a voltage of the anode of the light emitting element EL is initialized by being set to the voltage of the power supply line VSS.

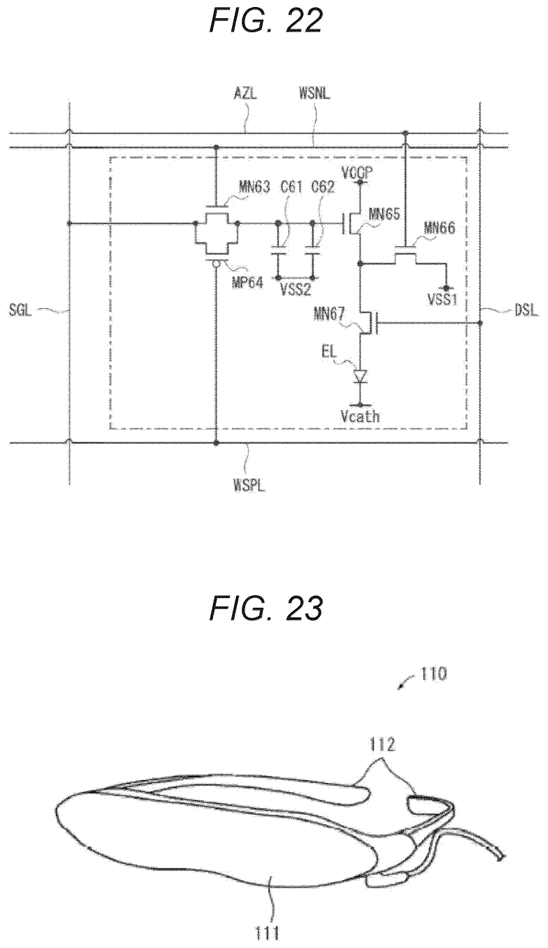

FIG. 22 is a diagram representing another configuration example of the pixel PIX. A signal of a control line WSNL and a signal of a control line WSPL are signals that are inverted with respect to each other.

The pixel PIX includes capacitors C61 and C62, transistors MN63, MP64, and MN65 to MN67 and the light emitting element EL. The transistors MN63 and MN65 to MN67 are N-type MOSFETs, and the transistor MP64 is a P-type MOSFET. The transistor MN63 has the gate connected to the control line WSNL, the drain connected to the signal line SGL and the source of the transistor MP64, and the source connected to the drain of the transistor MP64, the capacitors C61 and C62, and the gate of the transistor MN65. The transistor MP64 has the gate connected to the control line WSPL, the source connected to the signal line SGL and the drain of the transistor MN63, and the drain connected to the source of the transistor MN63, the capacitors C61 and C62, and the gate of the transistor MN65. The capacitor C61 includes, for example, a metal oxide metal (MOM) capacitor, and has one end connected to the source of the transistor MN63, the drain of the transistor MP64, the capacitor C62, and the gate of the transistor MN65, and the other end connected to a power supply line VSS2. Note that the capacitor C61 may be configured by using, for example, a MOS capacitor or a metal insulator metal (MIM) capacitor. The capacitor C62 includes, for example, a MOS capacitor, and has one end connected to the source of the transistor MN63, the drain of the transistor MP64, one end of the capacitor C61, and the gate of the transistor MN65, and the other end connected to the power supply line VSS2. Note that the capacitor C62 may be configured by using, for example, an MOM capacitor or an MIM capacitor. The transistor MN65 has the gate connected to the source of the transistor MN63, the drain of the transistor MP64, and one ends of the capacitors C61 and C62, the drain connected to the power supply line VCCP, and the source connected to the drains of the transistors MN66 and MN67. The transistor MN66 has the gate connected to a control line AZL, the drain connected to the source of the transistor MN65 and the drain of the transistor MN67, and the source connected to the power supply line VSS1. The transistor MN67 has the gate connected to the control line DSL, the drain connected to the source of the transistor MN65 and the drain of the transistor MN66, and the source connected to the anode of the light emitting element EL.

The capacitor C61 has a configuration that is the same as, for example, the capacitive element 55 illustrated in FIGS. 13 and 14. At this time, in the capacitive element 55, the plurality of metal flat plates 502 is connected to the power supply line VSS2, and the plurality of metal flat plates 504 is connected to the gate of the transistor MP65, and the capacitor C61 is constituted.

The capacitor C62 has a configuration that is the same as, for example, the capacitive element 55 illustrated in FIGS. 13 and 14. At this time, in the capacitive element 55, the plurality of metal flat plates 502 is connected to the power supply line VSS2, and the plurality of metal flat plates 504 is connected to the gate of the transistor MP65, and the capacitor C62 is constituted.

With this configuration, in the pixel PIX, by at least one of the transistors MN63 or MP64 being brought into the on state, a voltage between both ends of the capacitors C61 and C62 is set on the basis of the pixel signal supplied from the signal line SGL. The transistor MN67 is turned on and off on the basis of the signal of the control line DSL. The transistor MN65 causes a current corresponding to the voltage between both ends of the capacitors C61 and C62 to flow through the light emitting element EL during the period in which the transistor MN67 is in the on state. The light emitting element EL emits light on the basis of the current supplied from the transistor MP65. In this manner, the pixel PIX emits light with luminance corresponding to the pixel signal. The transistor MN66 may be turned on and off on the basis of the signal of the control line AZL. Furthermore, the transistor MN66 may function as a resistance element having a resistance value corresponding to the signal of the control line AZL. In this case, the transistor MN65 and the transistor MN66 constitute a so-called source follower circuit.

### 2. Application Example

Next, application examples of the display system described in the above embodiments and modifications will be described.

### Application Example 1

FIG. 23 is a diagram representing an example of an external appearance of a head mounted display 110. The head mounted display 110 includes, for example, ear hooking portions 112 to be worn on the head of a user on both sides of a glass-shaped display unit 111. The technology according to the embodiments and the like described above can be applied to the head mounted display 110 as such.

### Application Example 2

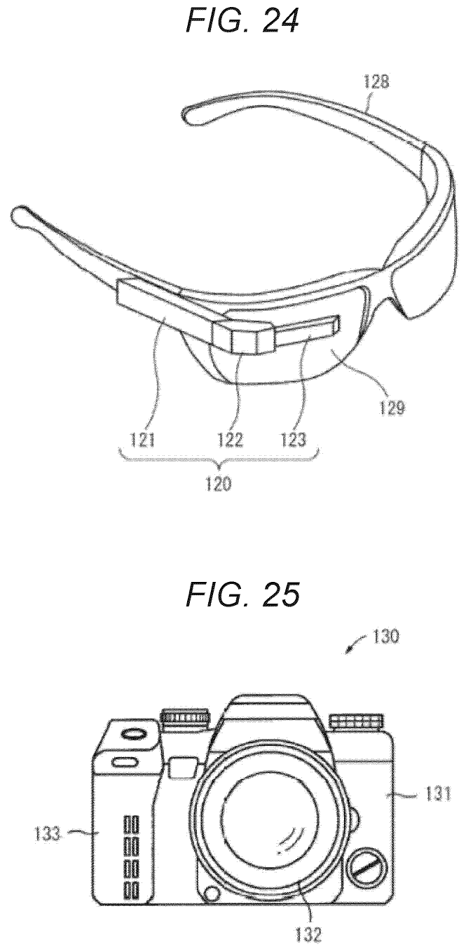

FIG. 24 is diagram representing an example of an external appearance of another head mounted display 120. The head mounted display 120 is a transmissive head mounted display including a main body portion 121, an arm portion 122, and a lens barrel portion 123. This head mounted display 120 is mounted on glasses 128. The main body portion 121 includes a control board for controlling operation of the head mounted display 120, and a display portion. This display portion emits image light of a display image. The arm portion 122 connects the main body portion 121 and the lens barrel portion 123 and supports the lens barrel portion 123. The lens barrel portion 123 projects image light supplied from the main body portion 121 via the arm portion 122 toward the eyes of the user via lenses 129 of the glasses 128. The technology according to the embodiments and the like described above can be applied to the head mounted display 120 as such.

Note that the head mounted display 120 is a so-called light guide plate type head mounted display, but is not limited thereto, and may be, for example, a so-called bird bath type head mounted display. This bird bath type head mounted display includes, for example, a beam splitter and a partially transparent mirror. The beam splitter outputs light encoded with image information toward the mirror, and the mirror reflects the light toward the eyes of the user. Both the beam splitter and the partially transparent mirror are partially transparent. With this arrangement, light from the surrounding environment reaches the eyes of the user.

### Application Example 3

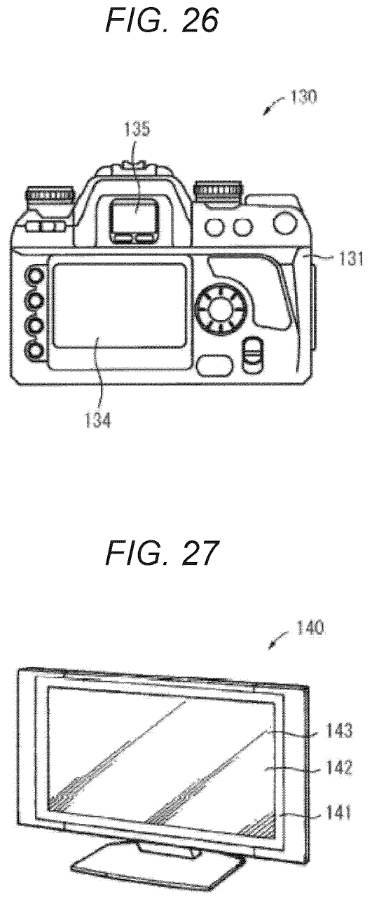

FIGS. 25 and 24 are diagrams representing an example of an external appearance of a digital still camera 130, FIG. 25 illustrating a front view and FIG. 26 illustrating a rear view. The digital still camera 130 is a lens interchangeable single-lens reflex type camera, and includes a camera main body portion (camera body) 131, an imaging lens unit 132, a grip portion 133, a monitor 134, and an electronic viewfinder 135. The imaging lens unit 312 is an interchangeable lens unit, and is provided near substantially the center of a front surface of the camera main body portion 311. The grip portion 133 is provided on a left side of the front surface of the camera main body portion 311, and a camera operator grips the grip portion 133. The monitor 134 is provided on the left side of substantially the center of the back surface of the camera main body portion 131. The electronic viewfinder 135 is provided on the upper part of the monitor 14 on the back surface of the camera main body portion 131. By looking into the electronic viewfinder 135, the camera operator can visually recognize the optical image of the subject guided from the imaging lens unit 132 and determine the composition. The technology according to the embodiments and the like described above can be applied to the electronic viewfinder 135.

### Application Example 4

FIG. 27 is a diagram representing an example of an external appearance of a television apparatus 140. The television apparatus 140 includes a video display screen portion 141 including a front panel 142 and a filter glass 143. The technology according to the above embodiment and the like described above can be applied to this video display screen portion 141.

### Application Example 5

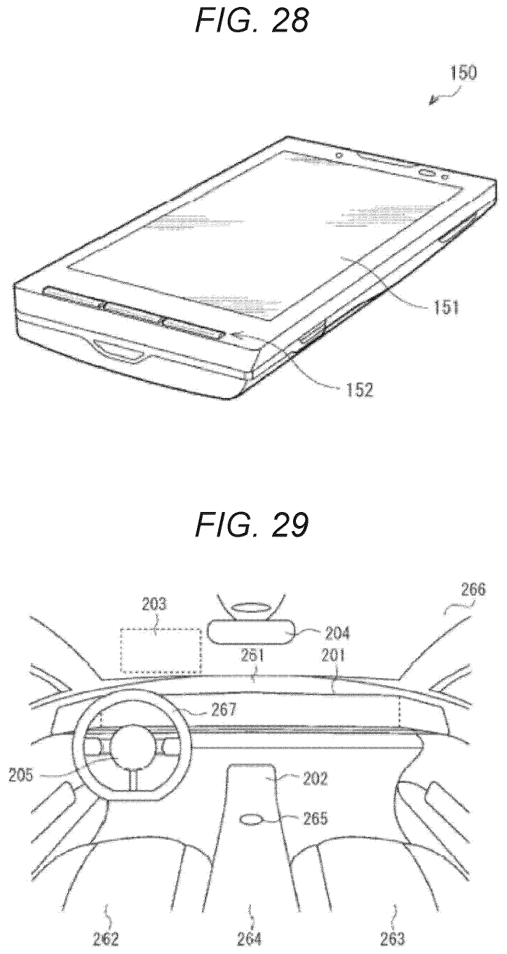

FIG. 28 is a view illustrating an example of an external appearance of a smartphone 150. The smartphone 150 includes a display portion 151 that displays various types of information, and an operation portion 152 including a button and the like for receiving an operation input by the user. The technology according to the embodiments and the like described above can be applied to the display portion 151.

### Application Example 6

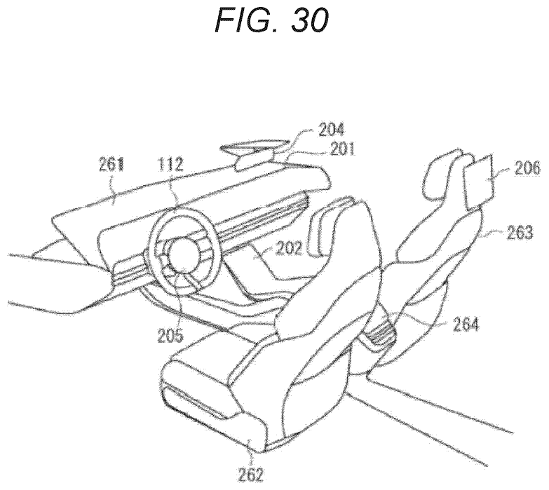

FIGS. 29 and 28 are diagrams representing a configuration example of a vehicle to which the technology of the present disclosure is applied, FIG. 29 illustrating an example of an inside of the vehicle as viewed from a rear portion of a vehicle 200, and FIG. 30 illustrating an example of the inside of the vehicle as viewed from a left rear portion of the vehicle 200.

The vehicle of FIGS. 29 and 28 includes a center display 201, a console display 202, a head-up display 203, a digital rear mirror 204, a steering wheel display 205, and a rear entertainment display 106.

The center display 201 is arranged on a dashboard 261 at a position facing a driver seat 262 and a passenger seat 263. FIG. 29 illustrates an example of the center display 201 having a horizontally long shape extending from the driver seat 262 side to the passenger seat 263 side, but the screen size and the arrangement location of the center display 201 are not limited thereto. The center display 201 can display information detected by various sensors. As a specific example, the center display 201 can display a captured image captured by an image sensor, a distance image to an obstacle in front of or on a side of the vehicle measured by a ToF sensor, a body temperature of an occupant detected by an infrared sensor, and the like. The center display 201 can be used to display, for example, at least one of safety-related information, operation-related information, a life log, health-related information, authentication/identification-related information, or entertainment-related information.

The safety-related information is information such as doze detection, looking-away detection, mischief detection of a child riding together, presence or absence of wearing a seat belt, and detection of leaving of an occupant based on detection results of the sensors. The operation-related information is gesture information regarding the operation of the occupant detected by using the sensor. The gesture may include operations of various facilities in the vehicle, for example, operations of an air conditioning equipment, a navigation device, an audio visual (AV) device, a lighting device, and the like. The life log include life logs of all the occupants. For example, the life log includes an action record of each occupant. By acquiring and storing the life log, the state of the occupant can be confirmed at the time when the accident occurs. The health-related information includes the body temperature of the occupant detected by using the temperature sensor and information on the health condition of the occupant estimated on the basis of the detected body temperature. Alternatively, the information on the health condition of the occupant may be estimated on the basis of the face of the occupant captured by the image sensor. Furthermore, the information on the health condition of the occupant may be estimated on the basis of an answer content of the occupant obtained by talking with the occupant by using the automatic voice. The authentication/identification-related information includes information such as a keyless entry function for performing face authentication by using a sensor and an automatic adjustment function of a seat height and position by face identification. The entertainment-related information includes operation information of the AV device by the occupant detected by the sensor, information of content suitable for the occupant detected and recognized by the sensor, and the like.

The console display 202 can be used to display, for example, the life log information. The console display 202 is arranged near a shift lever 265 in a center console 264 between the driver seat 262 and the passenger seat 263. The console display 202 can also display information detected by various sensors. Furthermore, the console display 202 may display an image of the periphery of the vehicle captured by the image sensor, or may display a distance image to an obstacle in the periphery of the vehicle.

The head-up display 203 is virtually displayed behind a windshield 266 in front of the driver seat 262. The head-up display 203 can be used to display, for example, at least one of the safety-related information, the operation-related information, the life log, the health-related information, the authentication/identification-related information, or the entertainment-related information. Because the head-up display 203 is often virtually arranged in front of the driver seat 262, the head-up display 203 is suitable for displaying information directly related to the operation of the vehicle, such as the speed of the vehicle, the remaining amount of fuel, and the remaining amount of the battery.

Because the digital rear mirror 204 can display not only the rear of the vehicle but also the state of the occupant in the rear seat, the digital rear mirror 204 can be used to display, for example, the life log information of the occupant in the rear seat.

The steering wheel display 205 is arranged near the center of a steering wheel 267 of the vehicle. The steering wheel display 205 can be used to display, for example, at least one of the safety-related information, the operation-related information, the life log, the health-related information, the authentication/identification-related information, or the entertainment-related information. In particular, because the steering wheel display 205 is close to the hands of the driver, the steering wheel display 205 suitable for displaying life log information such as the body temperature of the driver, or for displaying information regarding the operation of the AV device, air conditioning equipment, or the like.

The rear entertainment display 206 is attached to the back side of the driver seat 262 and the passenger seat 263, and is provided for viewing by an occupant in the rear seat. The rear entertainment display 206 can be used to display, for example, at least one of the safety-related information, the operation-related information, the life log, the health-related information, the authentication/identification-related information, or the entertainment-related information. In particular, because the rear entertainment display 206 is in front of the occupant in the rear seat, information related to the occupant in the rear seat is displayed thereon. The rear entertainment display 206 may display, for example, information regarding the operation of the AV device or air conditioning equipment, or may display a result of measuring the body temperature or the like of the occupant in the rear seat by a temperature sensor 5.

The technology according to the embodiments and the like described above can be applied to the center display 201, the console display 202, the head-up display 203, the digital rear mirror 204, the steering wheel display 205, and the rear entertainment display 206.

Note that the present technology can have the following configurations.
(1)

A capacitive element including:
a first layer body including a first metal body and a second metal body formed in a first layer; and
a second layer body including a third metal body and a fourth metal body formed in a second layer different from the first layer, in which
the first to fourth metal bodies are formed in an insulator, the first metal body and the third metal body have the same potential, and the second metal body and the fourth metal body have the same potential.
(2)

The capacitive element according to (1), in which the first metal body and the third metal body are connected by a first metal via, and the second metal body and the fourth metal body are connected by a second metal via.
(3)

The capacitive element according to (2), in which
the first metal body and the third metal body are connected by a plurality of the first metal vias, and the second metal body and the fourth metal body are connected by a plurality of the second metal vias, and
the plurality of first metal vias and the plurality of second metal vias are arranged in a lattice pattern.
(4)

The capacitive element according to (3), in which each of the first metal vias and each of the second metal vias adjacent to each other are arranged at an equal distance from each other.
(5)

The capacitive element according to (4), in which
the first layer and the second layer different from the first layer include parallel layers,
the first metal body and the third metal body have the same shapes and the second metal body and the fourth metal body have the same shapes,
the first metal body and the third metal body overlap each other in a direction orthogonal to the parallel layers, and
the second metal body and the fourth metal body overlap each other in a direction orthogonal to the parallel layers.
(6)

The capacitive element according to (5), in which
the first metal body includes a first metal having a rectangular parallelepiped shape and a plurality of second metals each having a rectangular parallelepiped shape orthogonal to the first metal,
the second metal body includes a third metal having a rectangular parallelepiped shape and a plurality of fourth metals each having a rectangular parallelepiped shape orthogonal to the third metal, and
the first metal and the third metal are arranged to face each other, and the plurality of second metals and the plurality of fourth metals are arranged to face each other.
(7)

The capacitive element according to (2), in which the first layer body further includes a fifth metal body, and the second layer body further includes a sixth metal body corresponding to the fifth metal body.
(8)

The capacitive element according to (7), in which
the first metal body 204 and the second metal body 202 form a first capacitance (cs), the second metal body 202 and the fifth metal body 200 form a second capacitance (csubb), and the first capacitance and the second capacitance have a ratio, and
the third metal body and the fourth metal body form a third capacitance, the fourth metal body and the sixth metal body form a fourth capacitance, and the third capacitance and the fourth capacitance have a ratio, the ratio between the third capacitance and the fourth capacitance being equal to the ratio between the first capacitance and the second capacitance.
(9)

The capacitive element according to (8), in which the first capacitance and the second capacitance are connected in series between a predetermined node.
(10)

The capacitive element according to (7), in which
the second metal body and the fourth metal body are connected by a plurality of the second metal vias, and the fifth metal body and the sixth metal body are connected by a plurality of third metal vias, and
each of the plurality of the second metal vias and each of the plurality of third metal vias are arranged at positions corresponding to each other.
(11)

The capacitive element according to (2), in which the first metal body and the second metal body form a first capacitance, and the third metal body and the fourth metal body form a second capacitance, the first capacitance and the second capacitance being equal to each other.
(12)

The capacitive element according to (11), in which each of the first to fourth metal bodies is formed in a flat plate shape.
(13)

A capacitive element configured by stacking, in an insulator, a plurality of layer bodies each including a first metal body and a second metal body formed in a same layer, in which
the first metal bodies of adjacent layers are connected by a plurality of first metal vias, and the second metal bodies of adjacent layers are connected by a plurality of second metal vias, and
the plurality of first metal vias and the plurality of second metal vias are arranged in a lattice pattern.
(14)

A display device in which a pixel circuit including the capacitive element according to (1) or (13) is arranged, in which
the pixel circuit further includes:
a drive transistor that drives a light emitting unit; and
a first transistor that writes a signal voltage, and
the capacitive element has the first metal body connected to a gate electrode of the drive transistor and the second metal body connected to a drain electrode of the drive transistor.
(15)

A display device in which a pixel circuit including the capacitive element according to (7) is arranged, in which
the pixel circuit further includes:
a drive transistor that drives a light emitting unit;
a first transistor that writes a signal voltage; and
a second transistor that controls light emission/non-light emission of the light emitting unit, and
the capacitive element has the first metal body connected to a gate electrode of the drive transistor, a second metal body connected to a source electrode of the drive transistor, and the fifth metal body connected to a node of a fixed potential.

Aspects of the present disclosure are not limited to the above-described individual embodiments, but include various modifications that can be conceived by those skilled in the art, and the effects of the present disclosure are not limited to those described above. In other words, various additions, modifications, and partial deletions may be made without departing from the conceptual idea and spirit of the present disclosure derived from the matters defined in the claims and equivalents thereof.

### REFERENCE SIGNS LIST

1 Display device
20, 20a, 20b, 20c Capacitive element
55 Capacitive element
400, 402, 404 Metal flat plate
406, 408, 409 Via
502, 504 Metal flat plate
506, 507 Via
DrvTr First transistor
Q1 First transistor
Q2 Drive transistor
WSTr First transistor

1. A capacitive element comprising:
a first layer body including a first metal body and a second metal body formed in a first layer; and
a second layer body including a third metal body and a fourth metal body formed in a second layer different from the first layer, wherein
the first to fourth metal bodies are formed in an insulator, the first metal body and the third metal body have a same potential, and the second metal body and the fourth metal body have a same potential.

2. The capacitive element according to claim 1, wherein the first metal body and the third metal body are connected by a first metal via, and the second metal body and the fourth metal body are connected by a second metal via.

3. The capacitive element according to claim 2, wherein
the first metal body and the third metal body are connected by a plurality of the first metal vias, and the second metal body and the fourth metal body are connected by a plurality of the second metal vias, and
the plurality of first metal vias and the plurality of second metal vias are arranged in a lattice pattern.

4. The capacitive element according to claim 3, wherein each of the first metal vias and each of the second metal vias adjacent to each other are arranged at an equal distance from each other.

5. The capacitive element according to claim 4, wherein
the first layer and the second layer different from the first layer include parallel layers,
the first metal body and the third metal body have same shapes and the second metal body and the fourth metal body have same shapes,
the first metal body and the third metal body overlap each other in a direction orthogonal to the parallel layers, and the second metal body and the fourth metal body overlap each other in a direction orthogonal to the parallel layers.

6. The capacitive element according to claim 5, wherein
the first metal body includes a first metal having a rectangular parallelepiped shape and a plurality of second metals each having a rectangular parallelepiped shape orthogonal to the first metal,
the second metal body includes a third metal having a rectangular parallelepiped shape and a plurality of fourth metals each having a rectangular parallelepiped shape orthogonal to the third metal, and
the first metal and the third metal are arranged to face each other, and the plurality of second metals and the plurality of fourth metals are arranged to face each other.

7. The capacitive element according to claim 2, wherein the first layer body further includes a fifth metal body, and the second layer body further includes a sixth metal body corresponding to the fifth metal body.

8. The capacitive element according to claim 7, wherein
the first metal body and the second metal body form a first capacitance, the second metal body and the fifth metal body form a second capacitance, and the first capacitance and the second capacitance have a ratio, and
the third metal body and the fourth metal body form a third capacitance, the fourth metal body and the sixth metal body form a fourth capacitance, and the third capacitance and the fourth capacitance have a ratio, the ratio between the third capacitance and the fourth capacitance being equal to the ratio between the first capacitance and the second capacitance.

9. The capacitive element according to claim 8, wherein the first capacitance and the second capacitance are connected in series between a predetermined node.

10. The capacitive element according to claim 7, wherein
the second metal body and the fourth metal body are connected by a plurality of the second metal vias, and the fifth metal body and the sixth metal body are connected by a plurality of third metal vias, and
each of the plurality of the second metal vias and each of the plurality of third metal vias are arranged at positions corresponding to each other.

11. The capacitive element according to claim 2, wherein the first metal body and the second metal body form a first capacitance, and the third metal body and the fourth metal body form a second capacitance, the first capacitance and the second capacitance being equal to each other.

12. The capacitive element according to claim 11, wherein each of the first to fourth metal bodies is formed in a flat plate shape.

13. A capacitive element configured by stacking, in an insulator, a plurality of layer bodies each including a first metal body and a second metal body formed in a same layer, wherein
the first metal bodies of adjacent layers are connected by a plurality of first metal vias, and the second metal bodies of adjacent layers are connected by a plurality of second metal vias, and
the plurality of first metal vias and the plurality of second metal vias are arranged in a lattice pattern.

14. A display device in which a pixel circuit including the capacitive element according to claim 1 is arranged, wherein
the pixel circuit further includes:
a drive transistor that drives a light emitting unit; and
a first transistor that writes a signal voltage, and
the capacitive element has the first metal body connected to a gate electrode of the drive transistor and the second metal body connected to a drain electrode of the drive transistor.

15. A display device in which a pixel circuit including the capacitive element according to claim 7 is arranged, wherein
the pixel circuit further includes:
a drive transistor that drives a light emitting unit;
a first transistor that writes a signal voltage; and
a second transistor that controls light emission/non-light emission of the light emitting unit, and
the capacitive element has the first metal body connected to a gate electrode of the drive transistor, a second metal body connected to a source electrode of the drive transistor, and the fifth metal body connected to a node of a fixed potential.
